(19) United States
(12) Patent Application Publication
(10) Pub. No.: US 2026/0023910 A1
(43) Pub. Date: Jan. 22, 2026

(54) QUANTUM DOT AUTO-ANNOTATOR AND AUTOMATICALLY ANNOTATING EMPIRICAL DATA

(71) Applicant: Government of the United States of America, as represented by the Secretary of Commerce, Gaithersburg, MD (US)

(72) Inventors: Justyna Pytel Zwolak, Point of Rocks, MD (US); Brian Joseph Weber, Philadelphia, PA (US)

(21) Appl. No.: 19/277,333

(22) Filed: Jul. 22, 2025

Related U.S. Application Data
(60) Provisional application No. 63/673,882, filed on Jul. 22, 2024.

(51) Int. Cl. G06F 30/392

(52) U.S. Cl. CPC G06F 30/392

(57) ABSTRACT

A quantum dot auto-annotator system includes a processor and a non-transitory computer-readable medium. Stored on the medium is a data structure for a binarized threshold map representing charge transitions in a multi-dimensional parameter space of a quantum dot device. A model-building module contains logic for generating a plurality of polygonal models from the binarized threshold map, where each polygonal model corresponds to a polytopal domain. The medium further includes a statistical inferencing module with logic for clustering the polygonal models into one or more orientation-based domains based on geometric orientations of the plurality of polygonal models. A global state determination module then executes logic for assigning a probabilistic state vector to pixel locations within the orientation-based domains to generate an annotated charge stability diagram.

### CROSS-REFERENCE TO RELATED APPLICATION

This application claims the benefit of U.S. Provisional Patent Application Ser. No. 63/673,882 (filed Jul. 22, 2024), which is herein incorporated by reference in its entirety.

### STATEMENT REGARDING FEDERALLY SPONSORED RESEARCH

This invention was made with United States Government support from the National Institute of Standards and Technology (NIST), an agency of the United States Department of Commerce. The Government has certain rights in this invention.

### BACKGROUND

The present invention generally relates to the field of quantum computing and the automated control of semiconductor devices, and more particularly to techniques for automatically annotating empirical charge stability diagrams by geometrically modeling polytopal domains within a parameter space to generate probabilistic state labels.

The pursuit of scalable quantum computing has identified gate-defined semiconductor quantum dot (QD) arrays as a particularly promising platform for realizing coupled qubit systems. The operation of these devices hinges on the precise application of numerous electrostatic potentials via a complex architecture of metallic gates, a process essential for confining individual charge carriers into the single-electron regime and achieving the requisite qubit operational performance. The operational complexity is staggering. As the number of QDs, and thus qubits, in an array increases, the parameter space of gate voltages that must be precisely navigated grows exponentially, rendering purely manual, heuristic control by human operators not merely difficult, but fundamentally unfeasible for large-scale systems. Consequently, the field has pivoted significantly towards automating device control, with a considerable focus on leveraging the powerful pattern-recognition capabilities of machine learning (ML) and artificial intelligence (AI).

A foundational prerequisite for the efficacy of these supervised ML models is the availability of vast, accurately labeled datasets for training, validation, and testing. The prior art, however, is critically hampered by the means through which such datasets are generated. One approach relies on data from physics-based simulations, which often produce an idealized representation of the device's behavior. This simulated data frequently fails to capture the full spectrum of stochastic noise, material imperfections, and device-specific idiosyncrasies inherent in real-world experimental systems, creating a significant reality gap that can degrade the performance of ML models when deployed on actual hardware. The de facto alternative, manual annotation of experimentally acquired data, is likewise fraught with profound disadvantages. This process is prohibitively slow, extraordinarily labor-intensive, and requires the dedicated time of a small cadre of domain experts. More critically, manual labeling is inherently subjective, prone to human error and inconsistent classification, especially when confronted with noisy or ambiguous charge stability diagrams.

This data problem precipitates a more systemic challenge for the entire research community, namely, the lack of standardized experimental benchmarks. In mature machine learning disciplines, progress is often measured against common, publicly available datasets, such as the MNIST database for handwritten digits. The absence of analogous, large-scale, and reliably labeled experimental datasets in the quantum dot field precludes the systematic and rigorous benchmarking of proposed autotuning algorithms. Without such standards, it is difficult, if not impossible, to objectively compare the performance of disparate methods against one another or against more traditional tuning paradigms. This ambiguity significantly retards innovation and hinders the collective development of reliable and truly scalable control strategies necessary for fault-tolerant quantum computation.

It is therefore an objective of the present invention to provide a system and method for the automated, principled, and reproducible annotation of empirical quantum dot device data, generating high-fidelity labeled datasets without direct reliance on either idealized simulations or fallible human annotation and to facilitate the creation of standardized benchmarks for the quantum computing field, thereby overcoming the above-mentioned disadvantages of the prior art at least in part. Accordingly, a system and method for automatically annotating empirical data based on its intrinsic geometric and physical structure would be advantageous and would be favorably received in the art.

### BRIEF DESCRIPTION

One aspect of the present invention relates to a quantum dot auto-annotator system. A quantum dot may be understood as a semiconductor nanostructure that confines the motion of charge carriers in three spatial directions, leading to quantized energy levels akin to those of an atom. An auto-annotator system may be understood as an apparatus that algorithmically assigns descriptive labels or metadata to a given dataset without requiring direct human intervention.

It may be provided that the system comprises a processor and a non-transitory computer-readable medium in communication with the processor. A processor may be understood as the logic circuitry that responds to and processes the basic instructions that drive a computer system, while a non-transitory computer-readable medium may be understood as a tangible storage device, such as random-access memory or a solid-state drive, capable of persistently storing computer-executable instructions and data. This arrangement provides the physical hardware foundation for the system, ensuring that the operational logic of the subsequent modules is embodied in a definite physical structure and executed by a dedicated computational engine, thereby constituting a specific machine rather than an abstract concept.

The non-transitory computer-readable medium may contain a data structure for a binarized threshold map representing charge transitions in a multi-dimensional parameter space of a quantum dot device. A binarized threshold map may be understood as a data array where each element holds one of two values, representing the presence or absence of a charge transition at a corresponding coordinate in the device's parameter space. One technical advantage of this arrangement is the efficient transformation of raw, often noisy, analog sensor data into a simplified and computationally tractable digital format. By isolating the geometrically salient features, e.g., the lines of charge transition, from the background noise and stable regions, the system reduces the initial data complexity, which allows for more efficient and rapid processing by downstream modules and conserves computational resources.

The non-transitory computer-readable medium may further contain a model-building module having logic for generating a plurality of polygonal models from the binarized threshold map, wherein each of the plurality of polygonal models corresponds to a polytopal domain within the parameter space. A model-building module may be understood as a component of a computer program designed to create structured mathematical representations from input data. One advantage of this arrangement is the conversion of discrete, pixel-level information from the threshold map into a set of contiguous, mathematically defined geometric objects. This provides a more robust representation that is less susceptible to localized noise and data artifacts, improving the accuracy and reliability of the system's ability to characterize the underlying structure of the charge stability diagram.

The non-transitory computer-readable medium may further contain a statistical inferencing module having logic for clustering the plurality of polygonal models into one or more orientation-based domains based on geometric orientations of the plurality of polygonal models. A statistical inferencing module may be understood as a programmatic component that deduces properties of a population by analyzing a sample of data. This arrangement provides a principled mechanism for organizing the generated polygons into physically meaningful groups. One technical advantage is that by classifying the polygonal models based on their intrinsic geometric orientation, the system can autonomously segment the parameter space into distinct operational regimes of the quantum dot device without relying on pre-programmed templates or human input, which enhances the system's adaptability across different device architectures and improves the overall efficiency of the annotation process.

The non-transitory computer-readable medium may further contain a global state determination module having logic for assigning a probabilistic state vector to pixel locations within the one or more orientation-based domains to generate an annotated charge stability diagram. A global state determination module may be understood as a component responsible for synthesizing intermediate classifications into a final, comprehensive data output. This arrangement provides for the final, useful output of the system by transforming the clustered geometric models into a scientifically rich and interpretable map. One technical advantage of assigning a probabilistic state vector, rather than a deterministic label, is the system's ability to numerically represent uncertainty and capture the physics of gradual transitions between different quantum states. This produces a more accurate and reliable annotated diagram, increasing its value as a benchmark dataset for training other machine learning models or for real-time device diagnostics.

One aspect of the present invention relates to a method for automatically annotating empirical data from a quantum dot device. Empirical data may be understood as information derived directly from physical experiment and observation, as opposed to purely theoretical calculation. A quantum dot device may be understood as a physical apparatus, typically fabricated from semiconductor materials, designed to confine and manipulate individual charge carriers in nanoscale regions.

It may be provided that the method comprises receiving, by a processor, a binarized threshold map derived from experimental measurements of charge stability in the quantum dot device, the binarized threshold map representing charge transitions within a multi-dimensional parameter space. Charge stability may be understood as a condition in a quantum dot system where the electron number is fixed against small perturbations, while a multi-dimensional parameter space is the space defined by the full range of operational variables, such as the numerous gate voltages controlling the device. This step provides the technical advantage of transforming raw, often continuous and noisy, experimental sensor readings into a definite, digital data structure. This conversion improves the overall efficiency of the method by reducing the computational burden and focusing the subsequent analysis specifically on the discrete loci of physical interest, the charge transitions, thereby enabling a more targeted and resource, efficient execution by the processor.

The method may further comprise generating, by the processor, a plurality of polygonal models corresponding to a plurality of polytopal domains within the parameter space by performing a geometric analysis of the binarized threshold map. A geometric analysis may be understood as the application of mathematical principles of geometry to extract information about shapes, sizes, and relative positions of features within the data. One technical advantage of this step is the creation of a higher-level, structural representation of the device's behavior. Instead of operating on disconnected pixels, the method constructs coherent polygonal objects that are inherently more robust to local noise, gaps, or imperfections in the binarized threshold map. This improves the accuracy and reliability of the overall annotation process by basing subsequent steps on stable, mathematically, defined shapes rather than raw pixel data.

The method may further comprise clustering, by the processor, the plurality of polygonal models into one or more orientation-based domains based on a statistical analysis of geometric orientations of the plurality of polygonal models. Clustering may be understood as the unsupervised grouping of objects such that objects within a single group are more similar to one another than to objects in other groups. This arrangement provides an automated and principled means of segmenting the entire parameter space. By leveraging the intrinsic geometric property of orientation as the primary classification feature, the method can autonomously identify and delineate distinct physical regimes of the quantum dot device, a novel approach that enhances the method's functionality and utility by making it adaptable to different device architectures without a need for pre-defined templates.

The method may further comprise generating, by the processor, an annotated charge stability diagram by assigning a probabilistic state vector to a plurality of pixel locations within the one or more orientation-based domains, the annotated charge stability diagram providing a physically-principled classification of operational regimes of the quantum dot device. A probabilistic state vector may be understood as a set of values where each value represents the likelihood of an element belonging to a particular class. This final step yields the tangible, technical result of the process. One advantage of this step is the enhanced performance and accuracy of the output; by assigning probabilities, the method quantitatively captures the physical reality of smooth, non, binary transitions between quantum states and conveys a measure of confidence in its own classification. This produces a more reliable and scientifically informative diagram, which represents a superior technical solution for creating benchmark datasets and performing device diagnostics.

### BRIEF DESCRIPTION OF THE DRAWINGS

The following description cannot be considered limiting in any way. Various objectives, features, and advantages of the disclosed subject matter can be more fully appreciated with reference to the following detailed description of the disclosed subject matter when considered in connection with the following drawings, in which like reference numerals identify like elements.

FIG. 1 shows, according to some embodiments, a schematic block diagram of a quantum dot auto-annotator system having a processor in communication with a non-transitory computer-readable medium, which in turn contains a model-building module, a statistical inferencing module, and a global state determination module.

FIG. 2 shows, according to some embodiments, a high-level flowchart depicting the primary steps of a method for automatically annotating empirical data, beginning with the receipt of a binarized threshold map and concluding with the generation of an annotated charge stability diagram.

FIG. 3 shows, according to some embodiments, a conceptual diagram illustrating the transformation of data, depicting the conversion of a noisy, unstructured input data map into a structured, segmented, and fully labeled output diagram representing distinct physical domains.

FIG. 4 shows, according to some embodiments, a schematic charge stability diagram and a corresponding state map, where panel (a) illustrates an idealized polygonal tiling of a two, dimensional voltage parameter space with integer labels indicating the charge configuration of each domain, and panel (b) illustrates the division of that parameter space into five distinct global state domains. In (a), the schematic charge stability diagram has visually evident tiling of the V_{P}_{₁}-V_{P}_{₂} plane by irregular polygons. The (m,n) labels indicate the QD charge configuration. As the plunger values are simultaneously increased, the two QDs merge as the electrons cease to localize on a single QD. The inset shows the potential landscape of the double, QD system. (b) The state map dividing the P₁-P₂ configuration space into five distinct global state domains, with ND indicating the region in the P₁-P₂ plane where no QDs formed, SD_{L}, SD_{C}, and SD_{R} denoting the left, central, and right single QD respectively, and DD denoting the double, QD state.

FIG. 5 shows, according to some embodiments, sample data plots illustrating the initial data and the binarized input for the system, where panels (a), (b), and (c) depict a simulated measurement, its numerical derivative, and the corresponding binary threshold map, respectively, and panels (d), (e), and (f) depict an experimentally acquired measurement, its derivative, and its corresponding binary threshold map. The sample 2D map (a) generated with the QD simulator and (d) acquired experimentally. The numerical derivative of the measurement showing the irregular polytope tiling of the 2D space for (b) the simulated measurement depicted in (a) and (e) the experimental data depicted in (d). The inset in (a) shows the ground truth state labels, created by the simulation. The binary threshold map that the QD auto-annotator requires as input for (c) the simulated measurement depicted in (a) and (f) the experimental data depicted in (d).

FIG. 6 shows, according to some embodiments, a visualization of the polygon model creation process, where panel (a) shows a fingerprint measurement, panel (b) shows the iterative convergence of observation points toward polygon centers, panel (c) shows the model creation for an ideal polygon, and panel (d) shows the model creation and correction for a noisy polygon. With respect to the polygon model creation, panel (a) shows a preview of a fingerprint measurement from a sample point (shown in pink) from the initial grid of observation points. A preview of the initial grid of sampled points is shown in gray. (b) A series of consecutive observation points selected by the model-building module with the intensity of the color indicating the progress of the algorithm. (c) Model creation for a nearly ideal polygon (right) and the resulting polygon (left). (d) A corrected set of rays for a noisy model a polygon (right) and the resulting polygon model (left).

FIG. 7 shows, according to some embodiments, a process of polygon tiling and domain filling, where panel (a) depicts the characteristic dominant orientations in the parameter space, panel (b) illustrates a preliminary tiling with inherent overlaps and gaps resulting from the modeling phase, and panel (c) displays the completed map after the remodeling process has resolved the imperfections. (a) The depiction of the characteristic left, center, and right dominant directions of the P₁-P₂ configuration space. (b) Fingerprint, modeled polygons for the device shown in FIG. 2(d), showing overlaps and gaps, and some misidentifications caused by noise and boundary effects. Overlaps are resolved by assigning to each contested point the observation point that it is closest to. Gaps are resolved by the expansion method described in the text. (c) The “filled in” map. In (b) and (c) the red, green, and blue colors indicate left, central, and right orientation, respectively. The gray color indicates the ND domain and the black color indicates pixels were not assigned to any polygon during the modeling phase.

FIG. 8 shows, according to some embodiments, a graphical representation of the heat-flow clustering method, illustrating how different kernel choices are parameterized over the circular domain of polygon orientations and how correctly selected kernels lead to clear and persistent clustering of points into left, center, and right orientation clusters. Various kernel choices in the heat flow clustering method. The x, axis parameterizes [symbol] and points are polygon orientations. Inset in each plot is the choice of kernel. Poor kernel choices lead to bad clustering, as shown in the first and last plots while correctly selected kernels lead to a potential showing clear and persistent clustering of points, as shown in the second and third plots. A majority of kernel selections will show the same or very similar clustering; then each point is assigned to the cluster it most persistently appears in. L,C, and R indicate left, center, and right orientation clusters, respectively.

FIG. 9 shows, according to some embodiments, a geometric analysis of a hexagonal charge stability cell, where panel (a) illustrates the division of the hexagonal cell into an upper and lower region for calculating physical ratios, and panel (b) depicts the cell's dimensions in terms of physical quantities derived from the constant interaction model. (a) The division of the hexagonal cell into an upper (above the centerline) and lower (below the centerline) polygon showing the cell roof (pink) and floor (green). (b) The polygonal cell's dimensions in terms of physical quantities in the constant interaction model.

FIG. 10 shows, according to some embodiments, final probabilistic domain decomposition for (a) a sample noisy simulated device shown in FIGS. 5(a) and (c) a sample experimental scan shown in FIG. 5(d) overlaying the charge sensor data. Regions with confidence in the dominant label of at least 70% represented as ringed areas for (b) the simulated data and (d) the experimental scan.

FIG. 11 shows, according to some embodiments, a graph of the performance of the quantum dot auto-annotator, plotting the agreement rate of the system's labels against ground, truth labels as a function of increasing noise levels across several distinct device state domains. The inset shows an overall performance across all domains and all devices for each noise level.

### DETAILED DESCRIPTION

A detailed description of one or more embodiments is presented herein by way of exemplification and not limitation.

Conventional approaches to generating labeled datasets for quantum dot (QD) device autotuning are beset by significant technical deficiencies that impede progress in the field of quantum computing. The reliance on physics-based simulations, while computationally convenient, produces datasets that are inherently idealized and fail to capture the complex noise profiles, material imperfections, and idiosyncratic artifacts of real, world experimental hardware. This creates a substantial reality gap, diminishing the performance and reliability of machine learning models when they are deployed on physical devices. The alternative, manual annotation of empirical data, is an equally flawed process. It is an exceedingly slow, labor, intensive, and costly endeavor that depends entirely on the availability of a limited pool of domain experts. More fundamentally, manual labeling is intrinsically subjective and susceptible to human error and inconsistency, leading to the creation of suboptimal and potentially biased datasets that lack the rigorous, objective quality needed for high, stakes scientific benchmarking. This absence of a scalable, reliable, and principled method for producing large-scale, high-fidelity experimental datasets has created a critical bottleneck, preventing the establishment of standardized benchmarks analogous to those that have catalyzed progress in other machine learning disciplines.

The quantum dot auto-annotator system (200) overcomes these deficiencies of subjective manual labeling and unrealistic simulation. It has been discovered that a quantum dot auto-annotator system (200) can autonomously produce principled, physically-grounded annotations of empirical data by performing a series of geometric and statistical analyses on the data's intrinsic structure. One technical advantage of the system (200) is its ability to operate directly on data derived from experimental measurements, thereby closing the reality gap left by purely simulated training sets. The system (200) comprises a processor (202) and a non-transitory computer-readable medium (204) in communication with the processor (202), an arrangement that embodies the system's logic in a definite physical apparatus and provides the computational engine for executing its unique method.

The non-transitory computer-readable medium (204) contains a data structure for a binarized threshold map (206) representing charge transitions in a multi-dimensional parameter space of a quantum dot device. This arrangement provides for a crucial initial data transformation, converting raw, continuous sensor readings into a discrete digital format that is more computationally efficient to process, thereby improving the speed and resource utilization of the entire annotation process. The non-transitory computer-readable medium (204) further contains a model-building module (208) having logic for generating a plurality of polygonal models (214) from the binarized threshold map (206), wherein each of the plurality of polygonal models (214) corresponds to a polytopal domain within the parameter space. A technical advantage of this arrangement is the improved reliability of the data representation; by abstracting pixel-level information into coherent geometric objects, the system becomes robust against localized noise and imperfections that would confound simpler analytical methods.

The non-transitory computer-readable medium (204) also contains a statistical inferencing module (210) having logic for clustering the plurality of polygonal models (214) into one or more orientation-based domains (216) based on geometric orientations of the plurality of polygonal models (214). This provides the improved functionality of autonomous and objective segmentation of the device's parameter space. By classifying the polygonal models based on their intrinsic geometric orientation, the system avoids the subjectivity of human judgment and the rigidity of pre-defined templates, enhancing its adaptability to novel device architectures. Finally, the non-transitory computer-readable medium (204) contains a global state determination module (212) having logic for assigning a probabilistic state vector (218) to pixel locations within the one or more orientation-based domains (216) to generate an annotated charge stability diagram (220). This step enhances the utility and accuracy of the system's output. By assigning a probabilistic vector rather than a deterministic label, the system quantitatively captures the physical nature of gradual state transitions and expresses a degree of confidence, producing a more nuanced and informative dataset that is superior for benchmarking and diagnostic applications.

In an embodiment, a quantum dot auto-annotator system (200), comprises a processor (202); and a non-transitory computer-readable medium (204) in communication with the processor (202), the non-transitory computer-readable medium (204) containing: a data structure for a binarized threshold map (206) representing charge transitions in a multi-dimensional parameter space of a quantum dot device; a model-building module (208) having logic for generating a plurality of polygonal models (214) from the binarized threshold map (206), wherein each of the plurality of polygonal models (214) corresponds to a polytopal domain within the parameter space; a statistical inferencing module (210) having logic for clustering the plurality of polygonal models (214) into one or more orientation-based domains (216) based on geometric orientations of the plurality of polygonal models (214); and a global state determination module (212) having logic for assigning a probabilistic state vector (218) to pixel locations within the one or more orientation-based domains (216) to generate an annotated charge stability diagram (220). In an embodiment, the model-building module (208) further includes logic for generating an extended point fingerprint (222) for an observation point (224) within the binarized threshold map (206) and logic for fitting one of the plurality of polygonal models (214) to the extended point fingerprint (222) by minimizing a Hausdorff distance between a set of terminal points of the extended point fingerprint (222) and a set of points on the one of the plurality of polygonal models (214). In an embodiment, the Hausdorff distance is a normalized I² Hausdorff distance. In an embodiment, the statistical inferencing module (210) includes logic for a heat-flow clustering algorithm (226) for determining a plurality of dominant directions from the geometric orientations of the plurality of polygonal models (214). In an embodiment, the heat-flow clustering algorithm (226) uses an ensemble of time-dependent kernels (228) with parabolic scaling to identify persistent cluster centers corresponding to the plurality of dominant directions. In an embodiment, the global state determination module (212) further includes logic for subdividing a central orientation-based domain (230) of the one or more orientation-based domains (216) into a double-dot (DD) domain (232) and a central single-dot (SDC) domain (234). In an embodiment, the logic for subdividing the central orientation-based domain (230) uses a quantitative hexagon-ness score (236) calculated for each of the plurality of polygonal models (214) located within the central orientation-based domain (230). In an embodiment, the quantitative hexagon-ness score (236) for one of the plurality of polygonal models (214) is a function of a first geometric ratio of a cell roof area to an upper cell area and a second geometric ratio of a cell floor area to a lower cell area of the one of the plurality of polygonal models (214). In an embodiment, the statistical inferencing module (210) further includes logic for calculating a model error score (238) for each of the plurality of polygonal models (214) based on the minimized Hausdorff distance and logic for discarding any of the plurality of polygonal models (214) having the model error score (238) exceeding a statistical threshold relative to a distribution of all model error scores. In an embodiment, each component of the probabilistic state vector (218) represents a probability for a device state selected from the group consisting of a no-dot (ND) state, a left single-dot (SDL) state, a central single-dot (SDC) state, a right single-dot (SDR) state, and a double-dot (DD) state.

In an embodiment, the quantum dot auto-annotator system (200) comprises a processor (202) and a non-transitory computer-readable medium (204) in communication with the processor (202). The functionality of this arrangement is to provide the physical and logical foundation for the system's operation, establishing it as a specific, tangible apparatus. The processor (202) acts as the computational engine, executing the instructions stored on the medium (204), while the medium (204) provides persistent storage for the system's operational logic and data structures. In one implementation, the processor (202) may be a central processing unit (CPU), a graphics processing unit (GPU) optimized for parallel computation, or a field-programmable gate array (FPGA) for high-speed, specialized processing. The non-transitory computer-readable medium (204) may be implemented as solid-state memory, a hard disk drive, or other forms of tangible data storage. A key benefit of this hardware configuration is that it grounds the subsequent algorithmic steps in a specific machine, enabling the practical, real, world transformation of empirical data. Variations may include a distributed system where multiple processors (202) and media (204) operate in concert over a network, or an integrated on-chip system where the processor (202) and medium (204) are co-located with the quantum device control electronics to reduce latency. As an example of use, a laboratory workstation containing the processor (202) and medium (204) is connected to the experimental apparatus, receiving raw data and executing the stored modules to produce the final annotated output.

The non-transitory computer-readable medium (204) contains a data structure for a binarized threshold map (206) representing charge transitions in a multi-dimensional parameter space of a quantum dot device. The function of the binarized threshold map (206) is to serve as the canonical input for the system's analytical modules, transforming raw sensor measurements into a computationally efficient digital format. This map (206) is implemented as a multi-dimensional array where each element's binary value indicates the presence or absence of a charge transition at that coordinate in the device's parameter space, which is typically defined by gate voltages. The generation of this map (206) involves applying a gradient filter to the initial experimental data to detect regions of rapid change, followed by applying a thresholding function. A principal benefit of this element is the significant improvement in processing efficiency; by removing the analog noise and stable regions, the system focuses its computational resources solely on the geometrically significant features, namely the transition lines. This data-reduction step enhances the speed and reliability of the entire annotation pipeline. Alternative implementations could involve the use of adaptive thresholding, where the cutoff value changes across the parameter space, or more sophisticated image processing techniques like morphological filtering to clean the map (206) prior to subsequent analysis. For instance, in a typical use case, raw current measurements from a charge sensor are processed to identify their numerical derivatives, and any point where the derivative's magnitude exceeds a pre-determined value is marked as a ‘1’ in the map (206), forming the initial data structure.

The non-transitory computer-readable medium (204) further contains a model-building module (208) having logic for generating a plurality of polygonal models (214) from the binarized threshold map (206), wherein each of the plurality of polygonal models (214) corresponds to a polytopal domain within the parameter space. The functionality of the model-building module (208) is to perform a crucial step of data abstraction, converting the disconnected, pixel-level information of the threshold map (206) into a collection of coherent, higher-level geometric objects. This is implemented through a set of algorithms that first identify candidate polygon centers and then generate a point fingerprint for each center by measuring the distance to the nearest transition lines along a dense set of rays. A polygonal model (214) is then fitted to this fingerprint by minimizing a cost function, such as the Hausdorff distance. A significant benefit of this approach is its inherent noise robustness. By fitting a complete geometric model, the module (208) can reliably bridge gaps in transition lines and ignore spurious noise pixels, leading to a more accurate and stable representation of the underlying charge stability structure than methods that rely on direct pixel analysis. Variations could include using different geometric fitting algorithms, alternative cost functions for minimization, or employing different heuristics for identifying and handling anomalous data points within a fingerprint. As an example of use, the model-building module (208) would process a region of the threshold map (206) that appears to contain a honeycomb, like pattern and, despite small gaps or noisy pixels, generate a set of distinct hexagonal polygonal models (214) that mathematically define that region.

The non-transitory computer-readable medium (204) also contains a statistical inferencing module (210) having logic for clustering the plurality of polygonal models (214) into one or more orientation-based domains (216) based on geometric orientations of the plurality of polygonal models (214). The function of this module (210) is to identify the macroscopic structure within the charge stability diagram by organizing the individual polygonal models (214) into physically meaningful groups. The implementation leverages a novel heat-flow clustering algorithm that analyzes the statistical distribution of the geometric orientations of the polygons to autonomously discover the dominant directional trends present in the data. A technical benefit of this module (210) is its adaptability and objectivity. The clustering is based on the intrinsic properties of the data, not on pre-defined templates or human supervision, which allows the system (200) to function reliably across a wide variety of quantum dot devices with different topologies and characteristics, thereby improving its utility. Alternative implementations might use other unsupervised clustering algorithms, such as k-means or DBSCAN, to group the orientations, though potentially with less robustness to complex distributions. In a typical application, the statistical inferencing module (210) receives the list of all generated polygonal models (214) and their calculated orientations and outputs a set of distinct clusters, each corresponding to an orientation-based domain (216) such as the left-dot, right-dot, or central-dot regions.

The non-transitory computer-readable medium (204) contains a global state determination module (212) having logic for assigning a probabilistic state vector (218) to pixel locations within the one or more orientation-based domains (216) to generate an annotated charge stability diagram (220). The functionality of this module (212) is to synthesize all the preceding analyses into the final, valuable output of the system. It is implemented by first using the identified orientation-based domains (216) to make a coarse state assignment, and then refining this assignment using physics-based rules, such as a quantitative hexagon-ness score, to further subdivide domains where appropriate. Its logic then calculates a probabilistic state vector (218) for each pixel, which quantifies the likelihood of that location belonging to each possible physical state. A key benefit of this final step is the enhanced accuracy and scientific value of the output. By assigning probabilities instead of deterministic labels, the annotated charge stability diagram (220) accurately reflects the physics of gradual transitions between quantum states and provides a quantitative measure of confidence. This produces a more reliable and informative dataset, enhancing its utility for the development of other machine learning models and for performing real-time device diagnostics. Variations of this module (212) could involve different physics-based rules tailored to other types of quantum devices or alternative methods for interpolating probabilities at domain boundaries. As an example of use, the global state determination module (212) would take the clustered domains (216), further separate the central domain into double-dot and single-dot regions based on the hexagon-ness score, and then generate a final color-graded image where the color at each pixel represents the components of its assigned probabilistic state vector (218).

The model-building module (208) may further include logic for generating an extended point fingerprint (222) for an observation point (224) and logic for fitting one of the plurality of polygonal models (214) to that fingerprint (222) by minimizing a Hausdorff distance. This functionality provides a specific and robust mechanism for constructing the polygonal models (214). The implementation involves emitting a series of rays from an observation point (224), recording the positions of the nearest charge transitions to create the extended point fingerprint (222), and then performing an optimization search to find the polygonal model (214) that best matches this set of terminal points according to the Hausdorff distance metric. A benefit of this arrangement is a significant improvement in the accuracy and reliability of the generated models, as the Hausdorff distance provides a holistic measure of fit that is inherently resilient to localized data gaps and noise artifacts that would confound simpler methods. Variations could involve using other distance metrics or different optimization routines for the fitting process. As an example of use, for a region of the binarized threshold map (206) representing a nearly, perfect hexagonal domain, this logic would generate a fingerprint (222) capturing the six sides and then find the ideal hexagonal model (214) that minimizes the distance to those points.

The Hausdorff distance may be a normalized I² Hausdorff distance. The function of specifying this particular metric is to enhance the performance and adaptability of the fitting process. It is implemented by calculating a root mean square deviation between the two point sets, normalized by the diameter of the sets to ensure scale invariance. A benefit of this implementation is the improved functionality of the system (200), as the normalization allows the model-building module (208) to analyze features of varying sizes across the charge stability diagram without requiring recalibration or prior knowledge of feature dimensions. Furthermore, the quadratic nature of the I² norm provides excellent smoothing properties, which enhances the reliability of the fit in the presence of stochastic imprecisions in the transition line locations. An alternative could be the use of an I¹ norm, which may be less sensitive to extreme outliers. For instance, a system (200) employing the normalized I² Hausdorff distance can analyze a charge stability diagram containing both large and small honeycomb cells with equal efficacy.

The statistical inferencing module (210) may include logic for a heat-flow clustering algorithm (226) for determining a plurality of dominant directions. The function of this specific algorithm is to autonomously identify the number and orientation of the primary physical axes within the charge stability diagram. The algorithm is implemented by treating the calculated polygon orientations as points on a circle and convolving these points with a diffusing kernel to identify where they naturally coalesce into stable clusters. This novel algorithm provides a significant advantage over conventional clustering methods by not requiring the number of clusters to be known a priori. This enhances the system's adaptability, allowing it to correctly identify the underlying topology of a device, whether it has two, three, or more dominant orientations, without any specific pre-programming. Variations could involve using standard clustering algorithms such as k-means, but this would involve adding a separate heuristic layer to determine the correct number of clusters. As an example of use, when analyzing data from a device with left, right, and central domains, the algorithm (226) will autonomously identify three persistent clusters corresponding to these three distinct orientations.

The heat-flow clustering algorithm (226) may use an ensemble of time-dependent kernels (228) with parabolic scaling. This feature refines the implementation of the clustering algorithm to improve its accuracy. The functionality is to test the stability of potential clusters across multiple spatial scales, which is implemented by applying a series of kernels with varying widths, controlled by a time-like parameter and a parabolic scaling law that mimics physical heat diffusion. A point's final cluster assignment is based on the cluster to which it belongs most persistently across this ensemble of scales. A benefit of this approach is enhanced reliability. By identifying features that are stable across multiple resolutions, the algorithm (226) effectively filters out spurious clusters that may appear only at a single scale due to noise, ensuring that only the truly intrinsic structural domains are identified. Alternatives could involve different scaling laws or a fixed-resolution analysis, though likely with a trade-off in accuracy. For example, a small, noisy group of polygons might form a temporary cluster under a narrow kernel, but this cluster would dissolve under a wider kernel, whereas the true, large domains would remain stable, proving their persistence.

The global state determination module (212) may further include logic for subdividing a central orientation-based domain (230) into a double-dot (DD) domain (232) and a central single-dot (SDC) domain (234). The function of this logic is to add a critical layer of physical classification that cannot be achieved by orientation analysis alone. It is implemented by first isolating all polygonal models (214) belonging to the central orientation-based domain (230) and then applying a second, more nuanced classification rule to differentiate them. This provides the improved functionality of being able to distinguish between the highly desirable, well-formed double-dot state and the degenerate, less, useful central single-dot state. This distinction is of high practical utility for quantum computing applications, as it allows for the precise identification of the operational regimes suitable for two, qubit gate operations. For example, this logic would analyze all polygons previously identified as having a central orientation and further classify them into two distinct sub, groups, DD (232) and SDC (234).

The logic for subdividing the central orientation-based domain (230) may use a quantitative hexagon-ness score (236). This score (236) functions as the specific, objective metric for performing the subdivision. It is implemented by calculating a numerical value for each polygonal model (214) in the central domain (230) based on its geometric properties. The benefit of using a quantitative score is that it makes the classification process deterministic, repeatable, and principled, avoiding the ambiguities of qualitative assessment. This leads to a more reliable and consistent annotation output. Variations could involve using other quantitative metrics, such as polygon area or aspect ratio, but the hexagon-ness score (236) is more directly linked to the underlying physics. In a typical use case, a well-formed hexagonal model (214) would receive a high score and be classified as part of the DD domain (232), while a distorted, quadrilateral, like model would receive a low score and be classified as SDC (234).

The quantitative hexagon-ness score (236) may be a function of a first geometric ratio of a cell roof area to an upper cell area and a second geometric ratio of a cell floor area to a lower cell area of the polygonal model. This specifies the precise, physically-grounded features used to calculate the score. The implementation involves a geometric deconstruction of the polygon based on its centerline, from which the areas of the roof and floor segments are calculated. The primary benefit of this novel implementation is that it creates a direct, quantitative link between an observable geometric property and a latent physical parameter of the quantum dot device, namely the inter-dot tunnel coupling. This allows the system (200) to extract nuanced physical information directly from the shape of the data, providing a more powerful and insightful annotation than would be possible otherwise. For instance, a model with very small roof and floor area ratios indicates strong coupling and is assigned a low score, while a model with larger ratios indicates the well-defined, weaker coupling characteristic of a true double-dot state and receives a high score.

The statistical inferencing module (210) may further include logic for calculating a model error score (238) and for discarding polygonal models (214) whose score exceeds a statistical threshold. This logic functions as a data quality control filter. Its implementation involves using the final, minimized Hausdorff distance from the fitting process as the model error score (238) for each polygon. The module (210) then analyzes the statistical distribution of all scores and flags any polygon whose score is a significant outlier. A key benefit is the enhanced reliability of the entire annotation pipeline. By preemptively removing polygonal models (214) that were poorly fitted, which are likely located in regions of extreme noise, the system (200) prevents this bad data from corrupting the subsequent clustering and state determination steps, leading to a more accurate final output. An alternative might involve discarding models based on other quality metrics, such as the number of anomalous rays in their fingerprint. As an example of use, if a model (214) has a model error score (238) more than two standard deviations above the mean, it is discarded and does not participate in the orientation clustering.

Each component of the probabilistic state vector (218) may represent a probability for a device state that includes or may be selected from the group consisting of a no-dot (ND) state, a left single-dot (SDL) state, a central single-dot (SDC) state, a right single-dot (SDR) state, and a double-dot (DD) state. This defines the specific, structured output format of the system. The implementation is an array of numerical values, summing to one, where each value corresponds to one of the canonical states of a double quantum dot device. The benefit of this explicit structure is that it provides an output that is immediately useful and interpretable to a person skilled in the art of quantum device control. This enhances the utility of the annotated charge stability diagram (220), making it directly applicable for creating benchmark datasets or for training other supervised machine learning algorithms that require a fixed and well-defined set of target classes. For example, a pixel location might be assigned the vector [0.0, 0.1, 0.8, 0.1, 0.0], indicating a high probability of being in the SD_{C} state but with some uncertainty or transitional character toward the SDL and SDR states.

An advantageous aspect of the quantum dot auto-annotator system (200) resides within the model-building module (208), specifically in its logic for generating a plurality of polygonal models (214) by minimizing a Hausdorff distance. The functionality of this process is to perform a robust and principled transformation of the discrete, often imperfect, pixel data of the binarized threshold map (206) into a set of continuous, mathematically complete geometric objects that accurately represent the underlying charge stability domains. This is implemented through a novel two-stage process. First, for a given observation point (224), the logic generates an extended point fingerprint (222) by computationally emitting a dense set of rays and recording the coordinate of the first charge transition line encountered along each ray. This creates a point cloud that effectively outlines the local polytopal domain. Second, the logic performs an optimization by searching for the ideal polygonal model (214) (e.g., a hexagon, pentagon, or quadrilateral) that minimizes the Hausdorff distance to this fingerprint point cloud. The system may specifically use a normalized I² Hausdorff distance, a metric that calculates the root mean square deviation between the two point sets and normalizes the result for scale invariance. A discrete gradient flow method can be employed to efficiently perform this minimization.

The benefits of this arrangement are substantial, directly contributing to the enhanced performance and reliability of the overall system. Unlike conventional methods that might rely on raw pixel data for classification, this geometric fitting provides a powerful form of noise immunity. The Hausdorff distance considers the entire shape of the domain, allowing the system to bridge small gaps in transition lines and ignore spurious noise pixels that would confound simpler algorithms, thus improving the accuracy of the resulting model. Using the normalized I² variant provides the further advantage of adaptability; the system (200) can analyze charge stability diagrams containing features of vastly different sizes without recalibration, improving its utility across a wide range of experimental conditions. This geometry-first approach is a departure from prior art ML techniques that rely on learning features from pixel patterns. As an example of use, if a binarized threshold map (206) contains a hexagonal cell with a portion of one side missing due to sensor noise, the fingerprinting logic will still capture the five complete sides and the endpoints of the incomplete side. The Hausdorff minimization logic will then correctly fit a complete hexagonal model to this data, effectively reconstructing the true domain shape in a mathematically principled manner, a task that would be challenging for conventional pattern matching.

Another advantageous element is the heat-flow clustering algorithm (226) implemented within the statistical inferencing module (210). The functionality of this algorithm is to autonomously discover the number and orientation of the macroscopic domains within the charge stability diagram by analyzing the geometric orientations of the previously generated polygonal models (214). The implementation treats the set of all polygon orientations as a distribution of points on a circular manifold. The algorithm (226) then applies an ensemble of time-dependent kernels (228) with varying spatial widths, governed by a parabolic scaling law that mimics the physical process of heat diffusion. The final classification of each polygon's orientation is determined by the cluster to which it belongs most persistently across this multi-scale analysis.

A benefit of this novel algorithm is the improved functionality and adaptability of the system (200). Unlike standard clustering algorithms such as k-means, the heat-flow method does not require the number of clusters (i.e., the number of distinct physical domains) to be specified beforehand. This allows the system (200) to automatically adapt to different device topologies without human intervention or re-programming, a significant enhancement in utility. Furthermore, the use of persistence across multiple scales provides superior reliability; it ensures that the system identifies only the true, underlying structural domains, while filtering out spurious, transient clusters that may arise from noise at a single length scale. While alternative clustering algorithms like DBSCAN could also be used, the heat-flow method is uniquely suited to this problem of identifying persistent features on a circular domain. As an example of use, consider a dataset where most polygons are oriented in one of three dominant directions, but a small, random subset is mis-oriented due to high noise. The heat-flow clustering algorithm (226) will identify the three large, stable clusters corresponding to the true domains, while the small, noisy group will fail to form a persistent cluster and will either be correctly assigned to neighboring domains or flagged as unreliable.

A further beneficial aspect is embodied in the global state determination module (212), which uses a quantitative hexagon-ness score (236) to perform fine-grained classification. The function of this score (236) is to distinguish between physically distinct states (specifically, the double-dot (DD) state and the central single-dot (SDC) state) that are otherwise indistinguishable based on their geometric orientation alone. The implementation of the score (236) is based on a direct link between geometry and physics. For each polygonal model (214) in the central orientation-based domain (230), the logic geometrically divides the polygon along its centerline into an upper cell and a lower cell. It then calculates a first geometric ratio of a cell roof area to the upper cell area and a second geometric ratio of a cell floor area to the lower cell area. The hexagon-ness score (236) is a function of these two ratios.

This implementation provides the benefit of extracting a latent physical parameter (the inter-dot tunnel coupling strength) from purely geometric properties of the measured data. This enhances the performance and utility of the system (200) by enabling a more physically nuanced and accurate annotation than would be possible through geometric classification alone. It allows the system to quantitatively assess the quality of the double-dot formation, a critical factor for quantum computing applications. An alternative might involve trying to estimate coupling from the thickness or slope of transition lines, but this is far less reliable and direct than the geometric area ratio approach. For example, a polygon that is a well-formed hexagon with large apertures will have large roof and floor area ratios, yielding a high hexagon-ness score (236), correctly identifying it as a desirable DD state. Conversely, a misshapen, collapsed polygon, corresponding to a state where the two dots have effectively merged, will have very small area ratios, yielding a low score and a classification as an SDC state.

In an embodiment, a method for automatically annotating empirical data from a quantum dot device, comprises receiving, by a processor (202), a binarized threshold map (206) derived from experimental measurements of charge stability in the quantum dot device, the binarized threshold map (206) representing charge transitions within a multi-dimensional parameter space; generating, by the processor (202), a plurality of polygonal models (214) corresponding to a plurality of polytopal domains within the parameter space by performing a geometric analysis of the binarized threshold map (206); clustering, by the processor (202), the plurality of polygonal models (214) into one or more orientation-based domains (216) based on a statistical analysis of geometric orientations of the plurality of polygonal models (214); and generating, by the processor (202), an annotated charge stability diagram (220) by assigning a probabilistic state vector (218) to a plurality of pixel locations within the one or more orientation-based domains (216), the annotated charge stability diagram (220) providing a physically-principled classification of operational regimes of the quantum dot device. In an embodiment, generating the plurality of polygonal models (214) further comprises emitting a dense set of rays from an observation point (224) to generate a point fingerprint (242) comprising a plurality of intersection points (240), and fitting one of the plurality of polygonal models (214) to the point fingerprint (242) by performing a minimization of a normalized I² Hausdorff distance between the plurality of intersection points (240) and points defining the one of the plurality of polygonal models (214). In an embodiment, the method further comprises, prior to generating the plurality of polygonal models (214), identifying a plurality of candidate polygon centers by defining an initial grid of observation points (224) within the binarized threshold map (206), and iteratively adjusting locations of the initial grid of observation points (224) toward centers of mass of their respective intersection points (240) until the locations of the observation points (224) stabilize. In an embodiment, clustering the plurality of polygonal models (214) comprises applying a heat-flow clustering algorithm (226) to the geometric orientations to identify a plurality of dominant directions corresponding to the one or more orientation-based domains (216). In an embodiment, applying the heat-flow clustering algorithm (226) comprises convolving point locations corresponding to the geometric orientations with an ensemble of time-dependent kernels (228) having parabolic scaling to identify persistent cluster centers. In an embodiment, generating the annotated charge stability diagram (220) further comprises subdividing a central orientation-based domain (230) into a double-dot (DD) domain (232) and a central single-dot (SDC) domain (234) based on a quantitative hexagon-ness score (236) calculated for each of the plurality of polygonal models (214) located within the central orientation-based domain (230). In an embodiment, calculating the quantitative hexagon-ness score (236) is based on a first geometric ratio of a cell roof area to an upper cell area and a second geometric ratio of a cell floor area to a lower cell area of a respective polygonal model, the first and second geometric ratios being interpreted through a constant interaction model for coupled quantum dots. In an embodiment, the method further comprises, prior to clustering the plurality of polygonal models (214), filtering the plurality of polygonal models (214) by calculating a model error score (238) for each of the plurality of polygonal models (214) based on the minimized normalized I² Hausdorff distance, and removing any of the plurality of polygonal models (214) whose model error score (238) is a statistical outlier relative to a distribution of all model error scores. In an embodiment, the method further comprises, after clustering and before generating the annotated charge stability diagram (220), a remodeling step comprising resolving overlaps (246) between adjacent polygonal models and filling in gaps (244) between the adjacent polygonal models to assign each pixel location in the binarized threshold map (206) to a unique polygonal model. In an embodiment, the probabilistic state vector (218) comprises a plurality of components, each component quantifying a probability that a pixel location corresponds to a device state selected from the group consisting of a no-dot (ND) state, a left single-dot (SDL) state, a central single-dot (SDC) state, a right single-dot (SDR) state, and a double-dot (DD) state.

The method for automatically annotating empirical data commences with the step of receiving, by a processor (202), a binarized threshold map (206) derived from experimental measurements of charge stability in a quantum dot device, where the binarized threshold map (206) represents charge transitions within a multi-dimensional parameter space. The functionality of this initial step is to ingest the pre-processed experimental data, providing a standardized and computationally tractable starting point for the subsequent analysis. This step is implemented by the processor (202) accessing a data structure, typically a multi-dimensional array, which has been generated by applying a gradient filter and a thresholding function to raw analog sensor data, thereby isolating the loci of charge transitions. A benefit of this step is a marked improvement in the efficiency of the overall method; by operating on a simplified, binary representation of the charge stability diagram, the processor (202) conserves significant computational resources that would otherwise be expended analyzing voluminous raw data with a low signal-to-noise ratio. Variations on this step could involve receiving the binarized threshold map (206) from local storage, via a network from a remote experimental apparatus, or in real-time as part of a closed, loop control system. As an example of use, a charge sensor's current measurements, taken while sweeping two gate voltages, are processed to create a binary image where pixels corresponding to charge transitions are marked, and this image is then loaded by the processor (202) as the binarized threshold map (206).

The method proceeds by generating, by the processor (202), a plurality of polygonal models (214) corresponding to a plurality of polytopal domains within the parameter space by performing a geometric analysis of the binarized threshold map (206). The function of this step is to perform a critical data abstraction, elevating the representation from a collection of discrete pixels to a set of coherent, mathematically, defined geometric shapes. This step is implemented by the processor (202) executing a set of geometric algorithms, which may include identifying candidate polygon centers and using a fingerprinting technique to generate a point cloud tracing the boundary of a local domain, to which a polygonal model (214) is then fitted. A technical benefit of this geometric analysis is the enhanced reliability and accuracy of the data representation. The generated polygonal models (214) are inherently robust to local defects in the binarized threshold map (206), such as small gaps in transition lines or spurious noise pixels, because the fitting procedure considers the global shape of the domain. This provides a novel solution that improves upon the fragility of conventional pixel-based classification schemes. Alternative implementations could involve different methods for fitting the models, such as machine learning-based segmentation, though this would sacrifice the principled, non-ML nature of the present method. For instance, upon receiving a threshold map (206) containing a honeycomb lattice, the processor (202) executes this step to produce a corresponding set of mathematically defined hexagonal models (214).

The method continues by clustering, by the processor (202), the plurality of polygonal models (214) into one or more orientation-based domains (216) based on a statistical analysis of geometric orientations of the plurality of polygonal models (214). This step's function is to identify the macroscopic physical regimes within the charge stability diagram by grouping the individual geometric shapes. The implementation involves the processor (202) first calculating a primary geometric orientation for each of the polygonal models (214) and then applying an unsupervised clustering algorithm to this set of orientations. A benefit of this step is the improved functionality of autonomous segmentation. Because the clustering is based on the intrinsic statistical properties of the data, the method can adaptively identify the correct number and type of physical domains for a given device without requiring pre-defined templates or human supervision, a substantial enhancement in utility and applicability over prior art. While alternative statistical techniques like k-means clustering could be used, they would typically require an additional heuristic layer to determine the correct number of clusters. As an example of use, the processor (202) can take the collection of generated polygonal models (214), calculate their orientations, and algorithmically group them into distinct clusters corresponding to the left-dot, right-dot, and central-dot domains (216) present in the diagram.

The method concludes by generating, by the processor (202), an annotated charge stability diagram (220) by assigning a probabilistic state vector (218) to a plurality of pixel locations within the one or more orientation-based domains (216), the annotated charge stability diagram (220) providing a physically-principled classification of operational regimes of the quantum dot device. The function of this final step is to synthesize the intermediate analyses into a useful, technical output of the method. The implementation involves assigning to each pixel location a vector (218) whose components represent the probability of that location corresponding to each of the possible physical states of the device, based on its inclusion in a clustered domain and refined by additional physics-based rules. A benefit of this step is the enhanced performance and accuracy of the final annotation. Assigning a probabilistic state vector (218), rather than a deterministic label, allows the method to quantitatively capture the physics of gradual state transitions and to convey a measure of confidence in its classification, yielding a more reliable and scientifically informative output. This provides a practical application and utility by generating superior datasets for benchmarking and device diagnostics. In a concrete example, a pixel at the boundary between a central and a left domain would be assigned a probabilistic state vector (218) with significant components for both states, accurately reflecting its transitional nature in the final annotated charge stability diagram (220).

The method for automatically annotating empirical data may be further refined by the specific implementation of the model generation step. The step of generating the plurality of polygonal models (214) may further comprise emitting a dense set of rays from an observation point (224) to generate a point fingerprint (242) and fitting one of the polygonal models (214) to that fingerprint (242) by minimizing a normalized I² Hausdorff distance. The function of this fingerprinting and fitting process is to provide a specific, noise-robust mechanism for translating the raw pixel data of the binarized threshold map (206) into a complete geometric object. This is implemented by the processor (202) performing a computational search for the polygonal model (214) whose vertices and edges best match the cloud of intersection points (240) that constitute the point fingerprint (242), where the quality of the match is quantified by the normalized I² Hausdorff distance. A technical benefit of this approach is the enhanced accuracy of the model generation; the I² norm inherently smooths over stochastic imprecisions in the data, while the Hausdorff distance as a whole ensures the global shape is captured even if local features like transition lines are discontinuous. Variations could involve using a different distance metric, such as an I¹ Hausdorff distance, which may offer different sensitivities to outliers. For instance, in a region with significant measurement noise causing a jagged transition line, this method would still generate a smooth-sided, accurate polygonal model (214) rather than a model that incorrectly traces the noisy contour.

The method may include a preparatory step that occurs prior to generating the polygonal models (214), wherein a plurality of candidate polygon centers are identified. The functionality of this step is to dramatically improve the computational efficiency of the overall method by intelligently selecting a small number of high-value locations for the more resource, intensive fingerprinting and model-fitting analysis. The implementation involves the processor (202) defining an initial, dense grid of observation points (224) and then iteratively moving each point toward the center of mass of its own local intersection points (240). This iterative process causes the observation points (224) to naturally coalesce at the centers of the polytopal domains, and a pruning algorithm is used to combine points that become sufficiently close until a stable set of candidate centers is achieved. A primary benefit of this step is the substantial reduction in processing time and power consumption, as it avoids the need to perform the complex model-fitting procedure at every point on the initial dense grid. An alternative implementation could use a density-based algorithm to find clusters in the stable regions of the map, though the iterative center-of-mass approach is more directly tied to the geometry of the domains themselves. As an example of use, an initial grid of tens of thousands of observation points (224) may be efficiently reduced to only a few hundred candidate centers, which are the only points that subsequently undergo the full fingerprinting and modeling process.

The step of clustering the plurality of polygonal models (214) may be implemented by applying a heat-flow clustering algorithm (226) to the geometric orientations. The specific function of this algorithm is to autonomously and reliably determine the number and orientation of the macroscopic physical domains present in the data. This is implemented by the processor (202) treating the set of polygon orientations as points on a circular manifold and applying a custom clustering routine that identifies groups of points that remain stable under a simulated diffusion process. A significant benefit of this novel algorithm is its enhanced adaptability and improved functionality compared to conventional clustering methods. It does not require the number of clusters to be known beforehand, which allows the method to correctly analyze devices with different underlying topologies without modification. This is a non, obvious solution to the problem of automated domain discovery in an unknown system. As an example of use, the processor (202) can apply the same heat-flow clustering algorithm (226) without modification to data from a simple double-dot device exhibiting three domains and to data from a more complex device exhibiting five or more domains, correctly identifying the topology in both cases.

The application of the heat-flow clustering algorithm (226) may be further particularized by convolving the point locations with an ensemble of time-dependent kernels (228) having parabolic scaling. This feature functions to increase the robustness and accuracy of the clustering result. The implementation involves the processor (202) testing the stability of potential clusters not at a single resolution, but across a range of resolutions, or scales, governed by the parabolic scaling of the kernels (228). A cluster is only considered valid if it persists across this entire ensemble. A key benefit of this multi-scale analysis is the enhanced reliability of the classification; it allows the algorithm (226) to distinguish between true, large-scale structural domains and small, spurious clusters that may arise from statistical noise at a single length scale. This improves the accuracy of the final domain map. For example, a small, noisy group of five mis-oriented polygons might appear as a distinct cluster when analyzed with a very narrow kernel, but this cluster would dissipate when analyzed with the wider kernels in the ensemble, whereas the true, large domains would remain stable across all kernels, thus validating their structural significance.

The step of generating the annotated charge stability diagram (220) may be improved by subdividing a central orientation-based domain (230) into a double-dot (DD) domain (232) and a central single-dot (SDC) domain (234) based on a quantitative hexagon-ness score (236). The function of this step is to perform a finer-grained, physically meaningful classification that is not possible using orientation alone. This is implemented by the processor (202) calculating a specific numerical score (236) for each polygonal model (214) within the central domain (230) that quantifies its deviation from an ideal hexagonal shape. This provides the improved functionality of being able to differentiate between the well-formed, computationally useful double-dot states and the collapsed, less useful single-dot states that share the same general orientation. This enhanced classification provides a more valuable and practical output for researchers in quantum computing. As an example of use, two polygons in the central domain (230) may both be classified by this step; one that is geometrically a well-formed hexagon will receive a high score and be labeled as DD (232), while another that is geometrically a distorted quadrilateral will receive a low score and be re-labeled as SDC (234).

The calculation of the quantitative hexagon-ness score (236) may be based on geometric ratios interpreted through a constant interaction model for coupled quantum dots. This step's functionality is to ground the geometric classification in established physical principles. It is implemented by the processor (202) performing a geometric deconstruction of each polygon to find a first ratio of a cell roof area to an upper cell area and a second ratio of a cell floor area to a lower cell area. These purely geometric ratios are then quantitatively related via the constant interaction model to the physical parameter of inter-dot tunnel coupling. A benefit of this step is that it enables the method to extract a latent physical property of the device from its observable geometric structure, providing an enhanced performance metric that yields a more insightful and accurate annotation. This technique provides quantitative physical parameter extraction. For example, a polygonal model (214) with small area ratios is interpreted as corresponding to high tunnel coupling (a merged dot), while a model with larger ratios corresponds to the weaker coupling of a well-defined double-dot.

The method may be further improved by filtering the plurality of polygonal models (214) prior to clustering, based on a model error score (238). The function of this step is to enhance the reliability of the overall process by acting as a data quality filter. It is implemented by the processor (202) using the final minimized normalized I² Hausdorff distance from the fitting procedure as the model error score (238) for each polygon. The processor (202) then analyzes the statistical distribution of these scores and removes any polygonal model (214) whose score is identified as a statistical outlier. A primary benefit is the improved accuracy of the subsequent clustering step; by preventing poorly-fitted models, which likely correspond to regions of extreme experimental noise, from participating in the analysis, the method ensures that the final domain boundaries are determined only by high-quality data. In a concrete example of use, if one polygonal model (214) has an error score (238) that is three standard deviations above the mean for all models, it is flagged as unreliable and discarded before the clustering algorithm is executed.

The method may further include a remodeling step after clustering and before generating the final annotated diagram (220). This step functions to create a complete and contiguous final map by resolving overlaps (246) and filling in gaps (244) between adjacent polygonal models. It is implemented by the processor (202) first examining any pixel locations that were claimed by more than one polygonal model (214) and assigning them to the model with the nearest center. It then performs an expansion algorithm, iteratively growing the territory of each polygon into adjacent unassigned space until all gaps (244) are filled. A key benefit of this step is the improved utility of the final output. It transforms a potentially fragmented collection of polygons into a single, comprehensive tiling of the entire parameter space, which is more useful for visualization and for use as a complete dataset. For example, if a thin, unassigned sliver of pixels exists between two domains, this step will assign those pixels to either the left or right domain based on proximity, creating a clean boundary.

The method's output, the probabilistic state vector (218), may comprise a plurality of components, where each component quantifies a probability that a pixel location corresponds to a specific device state selected from the group of canonical states: no-dot (ND), left single-dot (SDL), central single-dot (SDC), right single-dot (SDR), and double-dot (DD). The function of this specific vector structure is to standardize the output of the method into a format that is both physically interpretable and computationally useful. This implementation provides the benefit of enhanced utility, as the resulting annotated charge stability diagram (220) is directly suitable for use in training other machine learning algorithms, which often require data to be formatted with a fixed set of target classes and probabilistic outputs. As an example, the final output for any given pixel is not just a single label, but an array of five numbers, such as [0.0, 0.0, 0.1, 0.2, 0.7], clearly indicating a high probability of being in the DD state but with some transitional character toward the SD_{C} and SDR states.

It is contemplated that the quantum dot auto-annotator and automatically annotating empirical data with the quantum dot auto-annotator can include the properties, functionality, hardware, and process steps described herein and embodied in any of the following non, exhaustive list:
a process (e.g., a computer, implemented method including various steps; or a method carried out by a computer including various steps);
an apparatus, device, or system (e.g., a data processing apparatus, device, or system including means for carrying out such various steps of the process; a data processing apparatus, device, or system including means for carrying out various steps; a data processing apparatus, device, or system including a processor adapted to or configured to perform such various steps of the process);
a computer program product (e.g., a computer program product including instructions which, when the program is executed by a computer, cause the computer to carry out such various steps of the process; a computer program product including instructions which, when the program is executed by a computer, cause the computer to carry out various steps);
computer-readable storage medium or data carrier (e.g., a computer-readable storage medium including instructions which, when executed by a computer, cause the computer to carry out such various steps of the process; a computer-readable storage medium including instructions which, when executed by a computer, cause the computer to carry out various steps; a computer-readable data carrier having stored thereon the computer program product; a data carrier signal carrying the computer program product);
a computer program product including comprising instructions which, when the program is executed by a first computer, cause the first computer to encode data by performing certain steps and to transmit the encoded data to a second computer; or
a computer program product including instructions which, when the program is executed by a second computer, cause the second computer to receive encoded data from a first computer and decode the received data by performing certain steps.

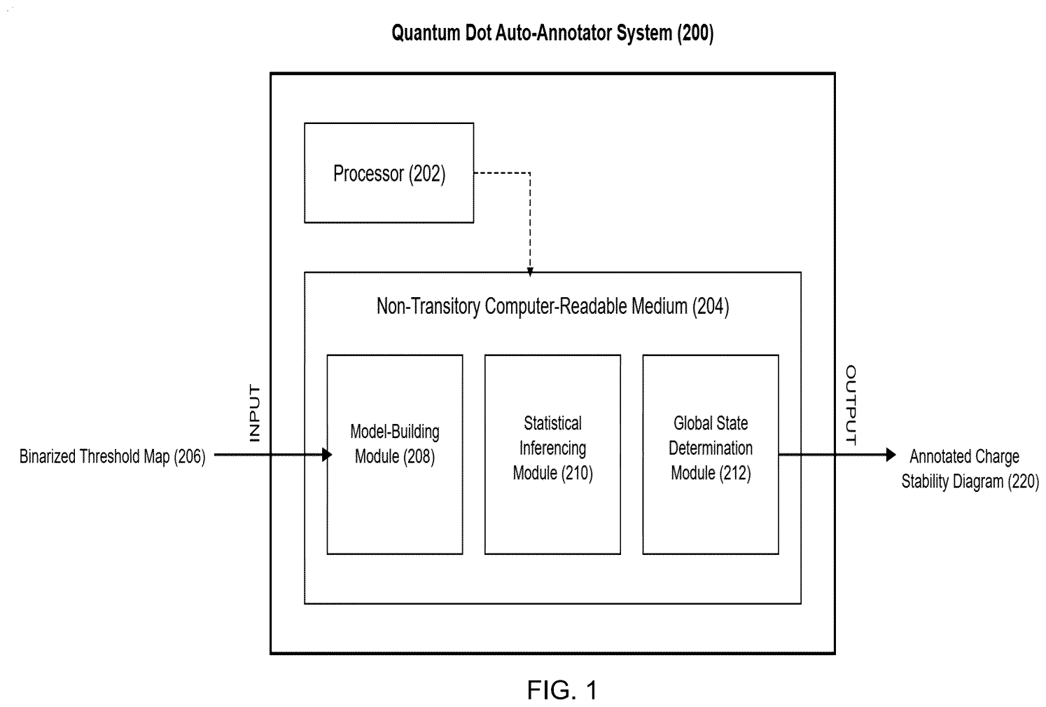

FIG. 1 shows a schematic block diagram of an embodiment of the quantum dot auto-annotator system (200), which represents a specific apparatus designed to perform the automated annotation of empirical data. The system (200) as a whole is architected, structured, and configured to receive a specific type of input data and, through a series of deterministic and physically-principled transformations, produce a structured and scientifically valuable output. The primary physical components of the system (200) are a processor (202) and a non-transitory computer-readable medium (204). These components are foundational, providing a physical embodiment of the system and ensuring it operates as a particular machine rather than an abstract or generalized concept.

The processor (202) is depicted as a distinct logical block within the system (200). Structurally, the processor (202) comprises logic circuitry, which can be implemented as a central processing unit (CPU), a graphics processing unit (GPU), a field-programmable gate array (FPGA), or a specialized application, specific integrated circuit (ASIC). Its interconnectivity is established through a communication link, represented by a dashed arrow, to the non-transitory computer-readable medium (204). The primary functionality of the processor (202) is to act as the computational engine for the entire system (200). It operates by fetching, decoding, and executing the computer, executable instructions that constitute the various software modules stored on the medium (204). For example, a multi, core CPU implementation would execute the system's algorithms, while a GPU implementation could offer enhanced performance by parallelizing computationally intensive tasks such as ray, casting or pixel, wise analyses. The benefit of this component is that it provides the necessary computational power to perform the complex geometric and statistical analyses at a speed suitable for practical laboratory use, thereby improving the efficiency of the data annotation workflow. Variations in implementation, such as using an array of processors, could be employed to further enhance processing speed for very large datasets.

The non-transitory computer-readable medium (204) is shown as a larger component that houses the system's operational logic. Structurally, this medium (204) is a tangible data storage device. Its implementation can take various forms, including volatile memory such as Random Access Memory (RAM) for active processing, or non, volatile memory such as a solid-state drive (SSD) or hard disk drive (HDD) for persistent storage of the software modules and data. The medium (204) is functionally interconnected with the processor (202), serving as the repository from which the processor (202) retrieves instructions and to which it writes processed data. Storing the system's logic on a non-transitory medium (204) provides the benefit of creating a persistent and definite article of manufacture, where the innovative steps are embodied in a concrete, executable form. This arrangement improves the reliability of the system (200) by ensuring that its operational logic is stable and consistently available. An alternative configuration could involve a hybrid memory architecture, using faster RAM for run, time operations and slower, non, volatile storage for archiving the system software and the generated annotated diagrams.

Residing on the non-transitory computer-readable medium (204) are three distinct software modules: the model-building module (208), the statistical inferencing module (210), and the global state determination module (212). These modules represent separate bodies of executable logic that operate in a sequential pipeline. The output of the model-building module (208) serves as the input for the statistical inferencing module (210), whose output in turn serves as the input for the global state determination module (212). This modular architecture provides the benefit of a structured and maintainable software design, where each stage of the complex annotation process is handled by a specialized component, improving the overall robustness of the system.

The data flow through the system (200) is explicitly illustrated, beginning with the input data structure, which is a binarized threshold map (206). This map (206), derived from physical measurements of a quantum dot device, is fed into the model-building module (208). The model-building module (208) has the specific function of transforming this low-level pixel data into a higher-level representation, a plurality of polygonal models (214). This abstraction is a functionality that enhances noise immunity.

The polygonal models (214) are then processed by the statistical inferencing module (210). The function of this module (210) is to analyze the geometric properties of the models and classify them into one or more orientation-based domains (216). This clustering step autonomously segments the charge stability diagram into physically meaningful regions.

Finally, the orientation-based domains (216) are passed to the global state determination module (212). This module's function is to synthesize all prior information and assign a probabilistic state vector (218) to pixel locations, thereby producing the final output of the system, a fully annotated charge stability diagram (220). This final diagram (220) represents a significant transformation of the initial input data (206). The system (200) takes an unstructured map of charge transition locations and converts it into a structured, physically classified map of device operational regimes, a process with significant practical utility in the field of quantum computing. The benefit of this overall data transformation is the creation of high-fidelity, reliably labeled datasets that can be used to benchmark new algorithms and train other machine learning models, thereby accelerating research and development.

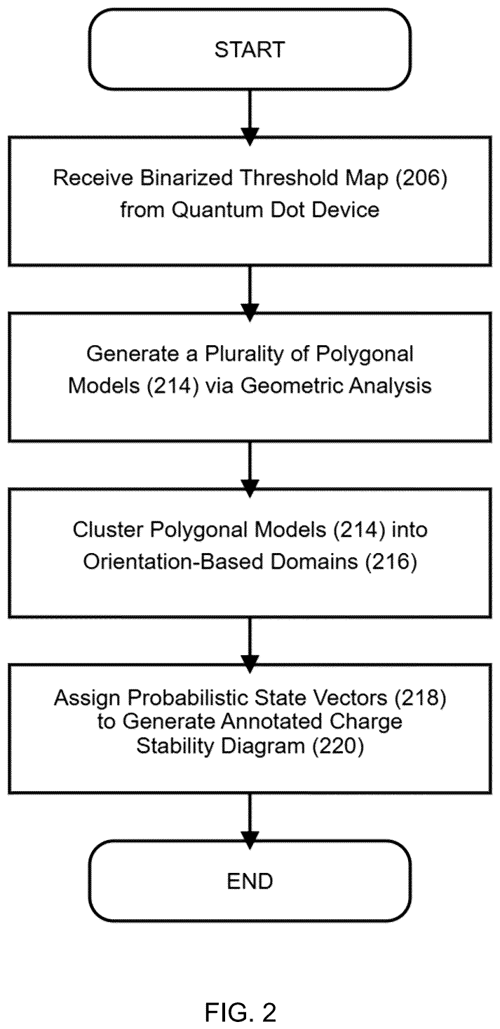

FIG. 2 presents a high-level flowchart that illustrates the logical and sequential progression of an embodiment of the method for automatically annotating empirical data from a quantum dot device. The diagram depicts the ordered series of transformations performed by a processor, beginning with a pre-processed data input and concluding with the generation of a structured, physically meaningful output. The flow of control and data between steps is represented by directional arrows, establishing a definite and repeatable procedure. The process commences at the START terminator, which signifies the initiation of the annotation method. From this point, the first operational step involves receiving, by a processor (202), a binarized threshold map (206) derived from experimental measurements of a quantum dot device. This input step is fundamental as it provides the specific data structure upon which all subsequent analyses are performed. The binarized threshold map (206) itself represents a transformation of raw physical measurements into a computationally tractable digital format, where the charge transitions are explicitly marked. The functionality of this step is to ingest the standardized input data, which can be implemented by the processor (202) reading the map (206) from a file on a storage medium or receiving it as a data stream from an active experimental setup. A benefit of this initial step is the improvement in computational efficiency, as it allows the processor (202) to focus its resources directly on the salient geometric features within the data.

Following the receipt of the input data, the method proceeds to the second step by generating a plurality of polygonal models (214) via a geometric analysis of the binarized threshold map (206). This step provides converting the low-level, pixel-based information into a collection of higher-level, coherent geometric objects. The functionality is to create a robust, intermediate representation of the charge stability domains that is less susceptible to local noise and imperfections. This is implemented by the processor (202) executing a series of algorithms, such as the fingerprinting and Hausdorff distance fitting procedures, to mathematically define a polygonal model (214) for each distinct polytopal domain detected in the map (206). A benefit of this step is the enhanced reliability of the system's internal data representation, which improves the accuracy of all downstream processing.

The third step in the sequence is the clustering of the plurality of polygonal models (214) into one or more orientation-based domains (216). The function of this step is to perform an autonomous segmentation of the entire parameter space by identifying macroscopic structural trends. The processor (202) implements this step by first calculating a geometric orientation for each of the generated polygonal models (214) and then applying a statistical clustering algorithm, such as the heat-flow clustering algorithm (226), to this set of orientations. This step provides the improved functionality of being able to automatically discover the number and nature of the distinct physical regimes within the charge stability diagram without requiring human supervision or pre-programmed, device, specific templates. The result of this step is a classification of each polygonal model (214) as belonging to a specific orientation-based domain (216), such as a left, right, or central domain.

The final operational step shown in the flowchart is the generation of the annotated charge stability diagram (220), which is accomplished by assigning probabilistic state vectors (218) to the pixel locations within the now-defined orientation-based domains (216). This step functions to synthesize all the previous geometric and statistical analyses into the final, tangible output of the method. The implementation involves the processor (202) applying physics-informed rules, which may include the use of a quantitative hexagon-ness score (236), to refine the classification and then calculate a vector of probabilities for each pixel. A benefit of this step is the superior accuracy and scientific utility of the output; the use of probabilistic vectors allows the system to quantitatively capture the physics of gradual state transitions and express a measure of confidence in its classification. This produces a more reliable and informative dataset. The process concludes at the END terminator, signifying that the fully annotated charge stability diagram (220) has been successfully generated and is available for use. This entire sequence represents a practical method for transforming raw physical measurements into high-value, structured scientific data.

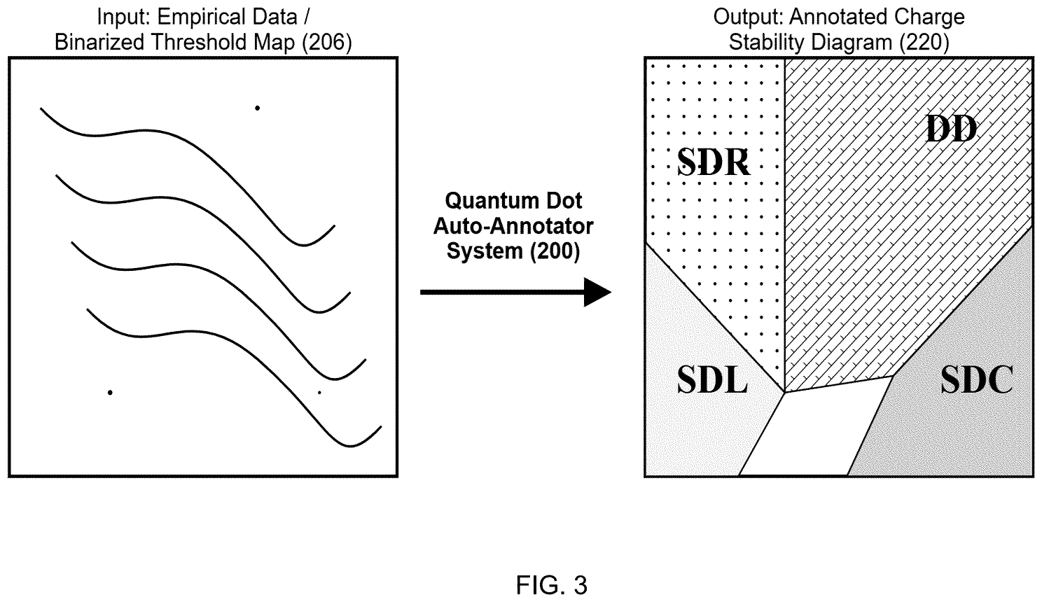

FIG. 3 provides a conceptual diagram illustrating the overall data transformation enabled by the quantum dot auto-annotator system (200). This figure visually represents the conversion of a raw, unstructured input data representation into a fully segmented, physically classified, and interpretable output diagram. The diagram is divided into an input stage on the left, a central transformation stage, and an output stage on the right. The input stage, on the left side of the figure, depicts the initial data state for the system. This is represented by a box labeled “Input: Empirical Data/Binarized Threshold Map (206).” The content of this box is a schematic representation of typical experimental data, characterized by a series of irregular, somewhat parallel, and occasionally discontinuous wavy lines. These lines represent the charge transitions recorded from a quantum dot device. The diagram also includes scattered, isolated points to represent the stochastic noise and measurement artifacts that are inherent in empirical data. This visual structure represents the fundamental technical problem, the input data is complex, noisy, and lacks an explicit, interpretable organization. It is an unstructured, pixel-level representation of physical phenomena that is not directly suitable for high-level analysis or for use in training other machine learning systems without significant, often manual, processing.

The central stage of the diagram consists of a large, directional arrow labeled “Quantum Dot Auto-Annotator System (200).” This element visually represents the process as the agent of transformation with the non-transitory computer-readable medium (204) containing the specialized software modules being applied to the input data. Its position between the input and output boxes illustrates that the system's operation is what bridges the gap between the raw data and the final, structured knowledge. The functionality of the system (200) as a whole is to perform the specific, ordered set of geometric and statistical analyses required to effect this transformation.

The output stage, on the right side of the figure, depicts the final result of the method, labeled “Output: Annotated Charge Stability Diagram (220).” In stark contrast to the input diagram, this output diagram is highly structured and organized. The parameter space is now partitioned into several contiguous regions, each with a distinct graphical pattern fill, such as diagonal lines, dots, or cross, hatching, to visually differentiate them. The boundaries between these regions are clean and well-defined. Each of these segmented regions is explicitly labeled with a physically meaningful state identifier, such as “ND” (No Dot), “SDL” (Single Dot Left), “SDR” (Single Dot Right), “SDC” (Single Dot Central), and “DD” (Double Dot). This output represents the successful extraction of the latent physical structure from the noisy input data.

The system (200) converts a computationally difficult and scientifically ambiguous data map into a clear, reliable, and physically-principled classification of the quantum dot device's operational regimes. The process enhances the accuracy of data interpretation by overcoming the noise and imperfections of the original measurements. The resulting annotated charge stability diagram (220) is a novel data product with significant value; it can be used directly for device diagnostics, for the development of advanced control protocols, and as a high-fidelity, standardized benchmark dataset for training and validating other machine learning algorithms in the quantum computing field. This automated generation of a labeled diagram from unlabeled empirical data represents a non, obvious solution to a long, felt need in the art.

In an embodiment, a method for manufacturing a quantum dot auto-annotator system (200), comprises providing a processor (202) and a non-transitory computer-readable medium (204); storing on the non-transitory computer-readable medium (204) a model-building module (208) having logic for transforming a binarized threshold map (206) of quantum dot device charge transitions into a plurality of polygonal models (214) representing polytopal domains within a parameter space; storing on the non-transitory computer-readable medium (204) a statistical inferencing module (210) having logic for classifying the plurality of polygonal models (214) into one or more orientation-based domains (216) based on a statistical clustering of geometric orientations of the plurality of polygonal models (214); and storing on the non-transitory computer-readable medium (204) a global state determination module (212) having logic for generating a final annotated charge stability diagram (220) by assigning a probabilistic state vector (218) to pixel locations within the one or more orientation-based domains (216). In an embodiment, storing the model-building module (208) comprises structuring the logic to generate one of the plurality of polygonal models (214) by fitting the one of the plurality of polygonal models (214) to an extended point fingerprint (222) through the minimization of a Hausdorff distance. In an embodiment, the Hausdorff distance is a normalized I² Hausdorff distance, and storing the model-building module (208) further comprises structuring the logic to use a discrete gradient flow method to perform the minimization. In an embodiment, storing the statistical inferencing module (210) comprises structuring the logic to implement a heat-flow clustering algorithm (226) that uses an ensemble of time-dependent kernels (228) to identify a plurality of dominant directions from the geometric orientations. In an embodiment, structuring the logic to implement the heat-flow clustering algorithm (226) comprises providing logic for parabolic scaling of the time-dependent kernels (228) to cause the time-dependent kernels (228) to imitate a one-dimensional heat flow. In an embodiment, storing the global state determination module (212) comprises structuring the logic to subdivide a central orientation-based domain (230) into a double-dot (DD) domain (232) and a central single-dot (SDC) domain (234). In an embodiment, structuring the logic to subdivide the central orientation-based domain (230) comprises providing logic to calculate a quantitative hexagon-ness score (236) for each of the plurality of polygonal models (214) within the central orientation-based domain (230). In an embodiment, structuring the logic to calculate the quantitative hexagon-ness score (236) comprises incorporating a physics-based interpretation of geometric ratios of a respective polygonal model, the geometric ratios relating to a cell roof area and a cell floor area of the respective polygonal model. In an embodiment, storing the statistical inferencing module (210) further comprises providing logic for filtering the plurality of polygonal models (214) based on a model error score (238) derived from the minimized Hausdorff distance. In an embodiment, the method further comprises integrating the model-building module (208), the statistical inferencing module (210), and the global state determination module (212) to cause the processor (202) to transform the binarized threshold map (206) representing raw physical measurements into the annotated charge stability diagram (220) representing a classification of quantum dot device operational states.

The method for manufacturing a quantum dot auto-annotator system (200) begins with the foundational step of providing a processor (202) and a non-transitory computer-readable medium (204). The function of this step is to establish the physical hardware substrate upon which the operational logic of the system (200) is built, ensuring the resulting apparatus is a tangible machine capable of executing the specific, stored instructions. This step is implemented by sourcing and assembling standard computing components, such as a central processing unit or a graphics processing unit for the processor (202), and a solid-state drive or random-access memory for the non-transitory computer-readable medium (204). Variations on this step may include providing a distributed computing architecture with multiple networked processors (202) or providing an integrated system where the hardware is co-located with experimental control instrumentation. As a concrete example of use, a manufacturer assembles a control workstation for a physics laboratory by installing a processor (202) and a non-transitory computer-readable medium (204) into a computer chassis.

The manufacturing method proceeds by storing on the non-transitory computer-readable medium (204) a model-building module (208) having logic for transforming a binarized threshold map (206) of quantum dot device charge transitions into a plurality of polygonal models (214) representing polytopal domains within a parameter space. The functionality of this step is to instantiate the system's core data abstraction capability, which converts a low-level, pixel-based representation of experimental data into a higher-level, more robust geometric representation. This is implemented by loading the compiled, executable code for the model-building module (208) onto the non-transitory computer-readable medium (204). Storing this specific module provides the resulting system (200) with a novel and non, obvious capability for noise, immune feature extraction, which improves the overall accuracy and reliability of the annotation process by ensuring subsequent analytical steps operate on stable geometric constructs rather than on volatile pixel data. The module (208) could be stored as a standalone application, a dynamic link library, or as firmware on a specialized device. For example, a software engineer compiles the source code for the geometric fitting algorithms and installs the resulting executable file on the provided medium (204), thereby completing this step of the manufacturing process.

The method continues by storing on the non-transitory computer-readable medium (204) a statistical inferencing module (210) having logic for classifying the plurality of polygonal models (214) into one or more orientation-based domains (216) based on a statistical clustering of geometric orientations of the plurality of polygonal models (214). The function of this step is to equip the system (200) with the logic necessary to autonomously discover the macroscopic structure within the charge stability diagram, segmenting the parameter space into physically meaningful regions. This is implemented by writing the compiled code for the statistical inferencing module (210), which may contain a heat-flow clustering algorithm (226), onto the medium (204). A significant benefit of storing this module is the improved functionality and adaptability of the final system; the logic's ability to determine the correct number of domains without prior knowledge of the device's specific topology makes the manufactured system (200) uniquely versatile and enhances its practical utility across a wide range of experimental contexts. As an example of use, after the model-building module (208) is stored, the code for the statistical inferencing module (210) is also installed on the same medium (204), making it available for execution by the processor (202).

The manufacturing method is completed by storing on the non-transitory computer-readable medium (204) a global state determination module (212) having logic for generating a final annotated charge stability diagram (220) by assigning a probabilistic state vector (218) to pixel locations within the one or more orientation-based domains (216). This step provides the system (200) with the critical component that synthesizes all intermediate analyses into the final, valuable technical output. The implementation involves loading the compiled code for the global state determination module (212), which contains the logic for applying physics-based rules and calculating the probabilistic state vectors (218), onto the medium (204). Storing this module confers the benefit of enhanced performance and accuracy on the manufactured system. By generating a probabilistic output, the system (200) produces a more reliable and scientifically nuanced classification, which improves the utility of the resulting annotated diagram (220) as a benchmark dataset or diagnostic tool. For instance, a technician installs a complete software suite onto the provided hardware, where the suite includes the code for the global state determination module (212), thereby finalizing the assembly of the operational quantum dot auto-annotator system (200).

In the method for manufacturing the quantum dot auto-annotator system (200), the step of storing the model-building module (208) may be further particularized by structuring its logic to generate a polygonal model (214) by fitting it to an extended point fingerprint (222) through the minimization of a Hausdorff distance. This manufacturing choice instantiates a specific, robust algorithm for data abstraction, where the logic is structured to perform ray, casting to create the fingerprint (222) and then execute an optimization routine to find the best, fit polygon. Providing this specific logic improves the reliability of the manufactured system, as the Hausdorff fitting procedure provides superior immunity to the noise and data gaps common in experimental settings. This fitting logic may be further refined by specifying that the Hausdorff distance is a normalized I² Hausdorff distance and by structuring the logic to use a discrete gradient flow method to perform the minimization. Storing logic that implements this specific normalized metric makes the final system more versatile, allowing it to accurately analyze features of varying scales without recalibration, while storing the discrete gradient flow logic provides a computationally efficient and stable means of performing the optimization, which improves the overall processing speed and performance of the manufactured apparatus.

The step of storing the statistical inferencing module (210) may be refined by structuring its logic to implement a novel heat-flow clustering algorithm (226) that uses an ensemble of time-dependent kernels (228) to identify a plurality of dominant directions. Manufacturing a system with this specific logic confers a significant advantage in adaptability, as the heat-flow algorithm autonomously determines the number of physical domains in the data, enhancing the system's utility across unknown device topologies. The logic for this algorithm may be further specified by providing for parabolic scaling of the time-dependent kernels (228), causing them to imitate a one-dimensional heat flow. Incorporating this specific scaling law into the stored logic enhances the reliability of the final product; this multi-scale analysis, inspired by physical diffusion, allows the system to effectively distinguish true structural features from noise, induced artifacts, thereby improving the accuracy of the final classification.

The step of storing the global state determination module (212) may comprise structuring the logic to subdivide a central orientation-based domain (230) into a double-dot (DD) domain (232) and a central single-dot (SDC) domain (234). Storing this specific subdivision logic provides the manufactured system with improved functionality, as it enables the identification of the highly desirable, well-defined double-dot regime crucial for quantum computing experiments. This subdivision logic may be further structured to calculate a quantitative hexagon-ness score (236) for each polygonal model (214) in the central domain (230), which makes the classification process deterministic and repeatable, thereby enhancing the consistency of the system's output. The logic for calculating this score (236) may be manufactured to incorporate a physics-based interpretation of geometric ratios of a respective polygonal model relating to a cell roof area and a cell floor area. Storing this novel, physics-based logic gives the manufactured system the unique capability to extract latent physical parameters, such as inter-dot coupling, directly from observable geometric features, a significant enhancement in performance that yields a more insightful and accurate annotation.

The manufacturing method may also include providing the statistical inferencing module (210) with logic for filtering the plurality of polygonal models (214) based on a model error score (238) derived from the minimized Hausdorff distance. Storing this quality, control logic makes the manufactured system more reliable by ensuring that poorly-fitted models from noisy regions are preemptively removed, preventing them from corrupting subsequent analyses and thus improving the accuracy of the final annotated diagram. Finally, the method may comprise the step of integrating the model-building module (208), the statistical inferencing module (210), and the global state determination module (212) to cause the processor (202) to transform the binarized threshold map (206) representing raw physical measurements into the annotated charge stability diagram (220) representing a classification of quantum dot device operational states. This integration step, implemented by storing a master application that calls the individual modules in sequence, is what assembles the individual logical components into the final, functional system, thereby providing the practical utility of converting raw experimental data into a high-level, physically meaningful output.

The distinctions between the quantum dot auto-annotator system (200) and conventional methodologies for analyzing quantum dot device data are rooted in a fundamental difference in operating principle. Existing techniques for data annotation generally rely on either direct human interpretation or supervised machine learning models. Manual annotation by human experts is inherently subjective, extraordinarily time-consuming, and not scalable to the volumes of data required for modern quantum device development. Supervised machine learning approaches, such as those employing convolutional neural networks to classify image patches, do not alleviate the core data generation problem; they require massive, pre-existing, and reliably labeled datasets for their training, a resource that is largely unavailable. These machine learning systems function as pattern recognizers, learning to associate pixel-level features with a given label, but they do not intrinsically understand the geometric or physical principles that govern the formation of those patterns.

The quantum dot auto-annotator system (200) operates on a completely different premise. Instead of treating the experimental data as an arbitrary image to be classified, the system (200) is structured to recognize that a charge stability diagram represents a specific mathematical object, specifically, an irregular tiling of the parameter space by convex polytopes. The system's unique contribution is its ability to directly model this underlying geometric structure from the empirical data itself, thereby generating the labels from first principles rather than learning to recognize them from a pre-labeled set. This is achieved through the specific logic stored on its non-transitory computer-readable medium (204). The model-building module (208) does not perform pattern matching; it performs a geometric analysis to construct a plurality of polygonal models (214), transforming the raw pixel data into a collection of coherent mathematical objects that are robust to experimental noise and imperfections.

This foundational difference is enabled by a series of unique algorithmic steps. Whereas conventional systems might use simple template matching, the model-building module (208) may employ a sophisticated fingerprinting technique coupled with the minimization of a Hausdorff distance to fit each polygonal model (214). This approach provides superior reliability by considering the global shape of a domain rather than just local features. Further, where other systems might require a user to specify the number of expected domains, the statistical inferencing module (210) can use a novel heat-flow clustering algorithm (226). This allows the system (200) to autonomously discover the correct number of orientation-based domains (216) by analyzing the statistical persistence of the geometric orientations, a significant improvement in adaptability and automation over existing methods.

Moreover, the system (200) integrates physical principles into its analysis in a way that conventional image classifiers cannot. The global state determination module (212) may calculate a quantitative hexagon-ness score (236), which is not merely a geometric measurement but a tool for extracting a latent physical parameter (the inter-dot tunnel coupling strength) directly from the shape of a polygonal model (214). This allows the system (200) to perform a more nuanced classification, for example, by distinguishing a well-formed double-dot (DD) state from a degenerate central single-dot (SDC) state, a distinction that is critical for quantum information processing. Finally, the system's generation of a probabilistic state vector (218) for its output provides a more accurate and scientifically useful representation of the device's behavior than a simple deterministic label, as it quantitatively captures the uncertainty inherent in gradual physical state transitions.

The articles and processes herein are illustrated further by the following Example, which is non, limiting.

### Example

Gate, defined semiconductor quantum dot (QD) arrays are a promising platform for quantum computing. However, presently, the large configuration spaces and inherent noise make tuning of QD devices a nontrivial task and with the increasing number of QD qubits, the human, driven experimental control becomes unfeasible. Recently, researchers working with QD systems have begun putting considerable effort into automating device control, with a particular focus on machine learning, driven methods. Yet, the reported performance statistics vary substantially in both the meaning and the type of devices used for testing. While systematic benchmarking of the proposed tuning methods is necessary for developing reliable and scalable tuning approaches, the lack of openly available standardized datasets of experimental data makes such testing impossible. The QD auto-annotator, a classical algorithm for automatic interpretation and labeling of experimentally acquired data, is a step toward rectifying this. QD auto-annotator leverages the principles of geometry to produce state labels for experimental double, QD charge stability diagrams and is a first step towards building a large public repository of labeled QD data.

Semiconductor, based quantum dot (QD) arrays, in which charge carriers are trapped in localized potential wells and information is carried in the form of electron spin qubits, are able to achieve the selectivity and connectivity needed for large-scale quantum computing¹. Due to the ease of control of the relevant parameters²⁻⁵, fast measurement of the spin and charge states⁶, relatively long decoherence times⁷⁻⁹, and their potential for scalability¹⁰⁻¹² QDs are gaining popularity as building blocks for solid-state quantum devices. However, because the individual charge carriers that makeup qubits have electrochemical sensitivity to minor impurities and imperfections, calibration and tuning of QD devices is a nontrivial and time-consuming process, with each QD requiring a careful adjustment of a gate voltage to define charge number, and multiple gate voltages to specify tunnel coupling between QDs for two, qubit gates or to reservoirs for reset and measurement. The relevant parameter space scales exponentially with QD number (dimensionality), making a control driven by prior knowledge and trial and error unfeasible. In semiconductor quantum computing, devices now have tens of individual electrostatic and dynamical gate voltages that must be carefully set to isolate the system to the single electron regime and to realize good qubit performance.

There have been numerous demonstrations of automation of the various phases of the tuning process for single and double, QD devices¹³. Some approaches seek to tackle tuning starting from device turn, on to coarse tuning¹⁴ or charge tuning¹⁵ while others assume that bootstrapping (calibration of measurement devices and identification of a nominal regime for further investigation) and basic tuning (confirmation of controllability and device characteristics) have been completed and focus on a more targeted automation of coarse and charge tuning¹⁶⁻²². Initial approaches relied mainly on the appealingly intuitive and relatively easy, to, implement conventional algorithms that typically involved a combination of techniques from regression analysis, pattern matching, and quantum control theory^{15,22,23}.

Over the past six years, researchers in the semiconductor QD community have begun to take advantage of the tools provided by the field of artificial intelligence and, more specifically, supervised and unsupervised machine learning (ML) to aid in the process of tuning QD devices¹³. When provided with proper training data, ML, enhanced methods have the flexibility of being applicable to various devices without any adjustments or re, training. However, ML models typically require large, labeled data sets for training and testing, and often lack information on the reliability of the ML prediction. Moreover, since the application of ML to QD tuning is a relatively new field of research, it lacks standardized measures of success. The performance reported in the various publications varies significantly in both the level and meaning of the reported numbers, making it hard (if not impossible) to benchmark the proposed techniques against more traditional tuning approaches or against one another¹³.

A simple but crucial component of success for the field is establishing standard data sets that can be used to assess the performance of new tuning methods and algorithms²⁴. So far, ML efforts for QD rely on data sets that either come from simulations^{17-21,25} (and thus may lack important features representing real, world noise and imperfections) or are labeled manually^{14,16} (and subject to qualitative and erroneous classification). Moreover, with a few exceptions, these data sets have not been made publicly available. Yet, systematic benchmarking of tuning methods on standardized data sets, analogous to the MNIST²⁶ and CIFAR²⁷ data sets from the general ML community or the QDataSet²⁸ designed to facilitate the development and training of quantum ML algorithms, is a crucial next step on the path to developing reliable and scalable auto, tuners for QD.

To initiate such efforts, an open data set, QFlow 2.0: Quantum dot data for machine learning²⁹, hosted and freely available at data.nist.gov, has been made available in 2022. This dataset includes a set of 1,599 idealized simulated measurements, the so, called charge stability diagrams, generated using the QD simulator³⁰, two sets of 1.5×10⁵ simulated noisy measurements³¹ with varying levels of noise as well as a small set of 12 experimentally acquired measurements. However, a systematic benchmarking of the already existing and new auto, tuning methods requires a significantly larger and standardized data set of experimental data²⁴. It also needs to represent data from different types of devices.

The White House Office of Science and Technology Policy (OSTP) announced 2023 to be launched as the Year of Open Science in the United States³² In response, the National Institute of Standards and Technology (NIST) has published a Federal Register Notice to seek public comment to identify existing large datasets relevant to QD experiments that may be useful for research, identify best practices for creating new, large datasets, and understand the challenges and limitations that may impact data access 33. Concurrent with this effort, NIST organized a Workshop on Advances in Automation of Quantum Dot Devices Control to serve as a starting point for discussions about the community's needs and interests related to research and development of semiconductor quantum computing technologies, methods of collaboration between partners from industry, academia, and the government, and development of a future roadmap for tuning large-scale devices 34. Among other aspects related to data standardization and sharing, the participants of the workshop discussed the need for the “development of a general, systematic, unbiased, and preferably automated labeling procedure ( . . . ) necessary if experimental data is to be included in a database intended for benchmarking” (see Sec. II.C in the workshop report²⁴).

To facilitate the systematic processing of large volumes of experimentally acquired 2D charge stability diagrams, we have been developing tools for automated and unbiased analysis and labeling, the QD auto-annotator, that will streamline the creation of the QD data database. The various QD device configurations create an irregular polytopal tiling of the charge stability diagrams where the specific type of a polytope conveys information about the corresponding device state (e.g., a single, QD or a double, QD for a double QD device). The polytope shapes and orientation provide information about electron behavior within the discrete states they represent (e.g., a left, central, or right single, QD). Since the transition between states is expected to occur monotonically, the polytopes with similar characteristics will cluster together, allowing the subdivision of charge stability diagrams into distinct domains where the system exhibits a consistent behavior. Since the resulting dataset is intended for the development and benchmarking of ML algorithms, it is particularly important that the tools used for processing and analysis of the experimental data are theoretically motivated and rooted in the principles of mathematics and physics. Our work provides a noise-robust automatic procedure for domain decomposition and characterization of individual polytopes within each domain.

The auto-annotator can be set up for double-QD data, and other polygonal tilings are readily understandable. The algorithm can be configured to recognize polytopal domains of many kinds and in higher dimensions, allowing it to go beyond the simple case of double, QD systems. This feature makes QD auto-annotator easily generalizable to data representing measurements of higher-dimensional QD arrays. It is also robust against the variability of the physical parameters of the system (e.g., the strength of the interdot coupling). By being rooted in geometry, the algorithm not only provides high-level labeling of data but also characteristics for explainable and interpretable features that can facilitate reliable diagnostics of failure modes.

Beneficially, the QD auto-annotator provides a large repository of labeled experimental data to streamline the ML research for QD automation. Methods

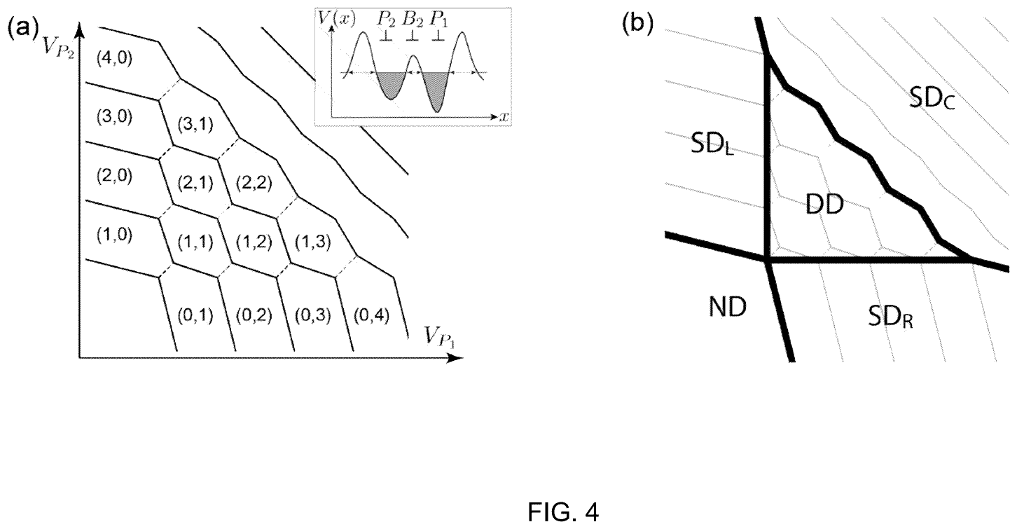

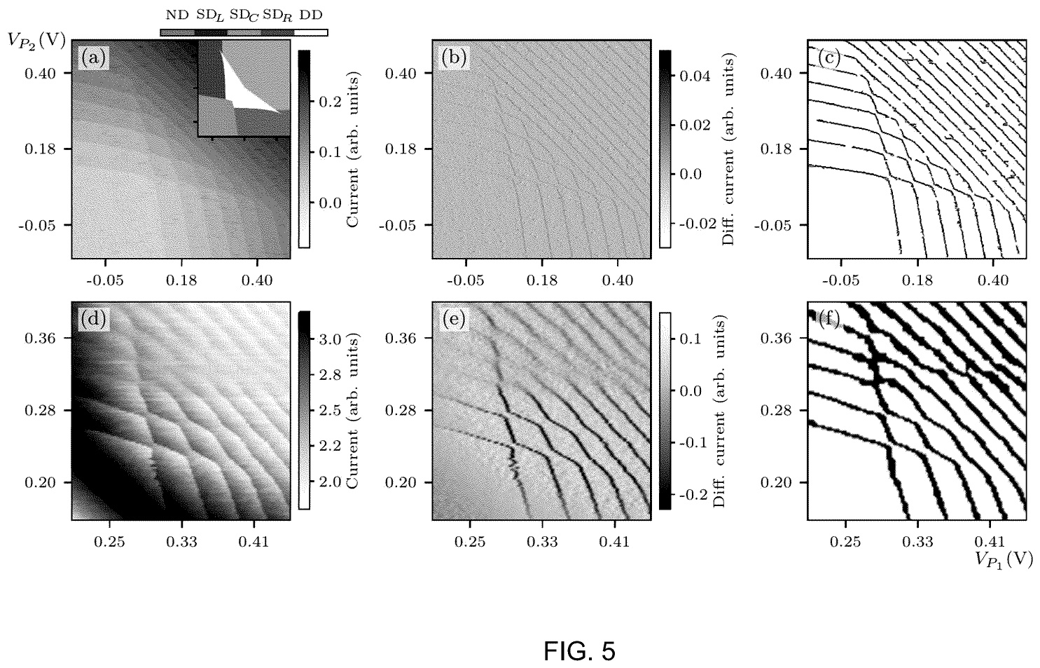

In semiconductor QD-based quantum computing, the aim is to confine electrons in potential wells using precise electrostatic controls. These come in the form of plunger gates, which create potential wells, and barrier gates, which create electrostatic barriers; see the inset in FIG. 4(a). The confinement wells, when filled, become QDs; in the case of two such dots, typically a total of five gates, two plungers and three barriers, are used to electrostatically confine electrons and separate them from the environment and each other. With fixed barrier potentials, the plunger potentials V_{P}_{₁},V_{P}_{₂} can vary through a dynamic range defining the relevant configuration space. The total charge within the device can be measured using a quantum point contact or a single electron transistor 3s. The discrete nature of the electrons leads to a charge stability diagram in which regions of the device's V_{P}_{₁}−V_{P}_{₂} configuration space show stable ground, state charge configurations. See FIG. 4(a) for an idealized depiction of a charge stability diagram, FIG. 5(a) for an example of a noisy simulated scan, and FIG. 5(d) a real, world example.

### QD Auto-Annotator Algorithm Overview

Due to the assumed weak tunnel coupling of QDs, the ground state charge configurations of the QD device can be described via the constant interaction model in which the possible charge configurations form convex polytopes³⁶⁻³⁸. A schematic of a 2D charge stability diagram with visually evident irregular tiling and charge configuration of each tile is shown in FIG. 4(a). The various polytopes' shape, size, and orientation provide information about the discrete states they represent. The goal of the QD auto-annotator is to create state, level decomposition of the configuration space into domains capturing the possible states of the device based on the polytopal tiling. The QD auto-annotator uses a classical algorithm to create a model of each polytope. Polytopes with similar characteristics cluster together, allowing the subdivision of the charge stability diagrams into distinct global state domains, where the system exhibits a consistent behavior. A sample division of a configuration space into a no QD (ND), a left, central, and right single, QD (SD_{L}, SD_{C}, and SD_{R}, respectively), and double, QD (DD) state subdivisions is depicted in FIG. 4(b).

The QD auto-annotator algorithm has three distinct phases: model building, statistical inferencing, and global state determination. The model building phase uses the fingerprinting method^{39,40} to collect the information necessary to build discrete polygonal models. In the statistical inferencing phase, gross features of the polygons, i.e., orientation, interior angles, number of edges, etc., are used to group the polygons into classes. Because noise effects can distort polygon models in unpredictable ways, this phase also makes noisiness and reliability determinations to differentiate between reliable and unreliable models. The final global state determination phase divides the scan into global state domains, by first using the grouping results from the statistical inferencing phase, and then creating models of the global domains based on underlying physical principles. Typically, the DD state grades into the SD_{L}, SD_{C}, or SD_{R} state without any sharp boundary as the interdot coupling between the QDs increases³⁸. To accommodate this, the QD auto-annotator algorithm examines each polygon individually and applies explicit external rules based on electron confinement physics³⁸ to assign a probability that a given polygon belongs to the DD or SD_{C} state.

Given that the fingerprinting method is error, prone in the presence of noise, the QD auto-annotator relies on high levels of measurement redundancy, which is easy to accommodate in the offline setting, i.e., when used to analyze pre, measured scans as opposed to data acquired in a real-time, along with certain statistical methods to obtain reliable state labeling.

### Simulated and Experimental Data Overview

An example of a simulated QD device measurement, analogous to ones typically acquired in the laboratory, its numerical derivative showing the polygonal tiling, and the corresponding threshold map are shown in FIG. 5(a), FIG. 5(b), and FIG. 5(c), respectively. Similar depictions for an experimentally acquired scan from the QFlow 2.0 dataset are shown in FIG. 5(d), FIG. 5(e), and FIG. 5(f), respectively. An inset in FIG. 5(a) shows the state map (available only for simulated data) corresponding to a measurement shown in FIG. 5(a). The x and y axes represent a subset of parameters changed in the experiments (here, the plunger gate voltages controlling the formation of the QDs, see inset in FIG. 4(a)), and the curves represent the device response to a change in QD electron occupation.

The simulated data used in this work is generated using a physics-based simulator of QD devices³⁰. Each simulated measurement is stored as a separate file that includes the physical parameters defining the QD device, the measurement range for each axis, the transport and charge sensor measurement, a ground, truth global state map, a ground state charge configuration map for the SD_{L}, SD_{C}, SD_{R}, and DD states, and the simulated noise level. The experimental data files contain the charge sensor data, the voltage range for each axis over which the measurement was performed, as well as information about the device used in the measurement.

### Data Preparation Module

The raw charge stability diagrams from both simulated and experimentally acquired measurements represent the QD device response to a change of a particular parameter (or parameters), with the value at each point (pixel) indicating the purported total charge on the device. The QD auto-annotator requires as an input a binarized version of the charge stability diagram which we call a threshold map. Regions where the charge configuration remains unchanged are labeled in the threshold map as 0 while pixels capturing the device response to a change in electron occupation, i.e., a voltage configuration where an electron moves into or out of the QD, are labeled as 1. An example of a binary threshold map for the simulated and experimentally acquired measurements shown in FIG. 5(a) and FIG. 5(d) are shown in FIG. 5(c) and FIG. 5(f), respectively.

Both simulated and experimental charge stability diagrams can be noisy and filled with numerous artifacts, some of which can be theoretically accounted for and some of which are simply stochastic. Moreover, the measurement characteristics can vary widely between the different types and designs of QD devices. The data denoising and binarization involve human input in the form of choosing local gradient thresholds and tuning gradient filters. For high, noise data, additional correlational strategies are employed to ameliorate labeling errors. The preprocessing of data is carried out outside of the QD auto-annotator.

### Model, Building Module

The first step of the QD auto-annotator is the creation of polygon models from the threshold map. The primary tool here is fingerprinting. Definition 1 [Point fingerprint in 2D] Let xₒ be an observation point sampled within a 2D charge stability diagram. A point fingerprint [symbol] at an observation point xₒ is a list of weighted distances from that point to the nearest charge transition line along evenly spaced one-dimensional (1D) measurements called rays^{39,40}.

The idea of using fingerprints to classify simple high, dimensional geometrical structures was first proposed in the context of cost, effective calibration of QD devices^{19,39,40}. However, while for ML, driven classification purposes the qualitative information about the boundaries defining the polytopes suffices, capturing the smooth transition between the states for the purpose of labeling the 2D charge stability diagrams requires full modeling of the structures of interest. In addition to fingerprints the model-building module requires also information about the orientation of the respective rays to determine the position of the terminal points, i.e., points in the 2D configuration space where rays cross transition lines. We call the fingerprint combined with a vector of ray orientations an extended point fingerprint.

### Localizing Observation Points

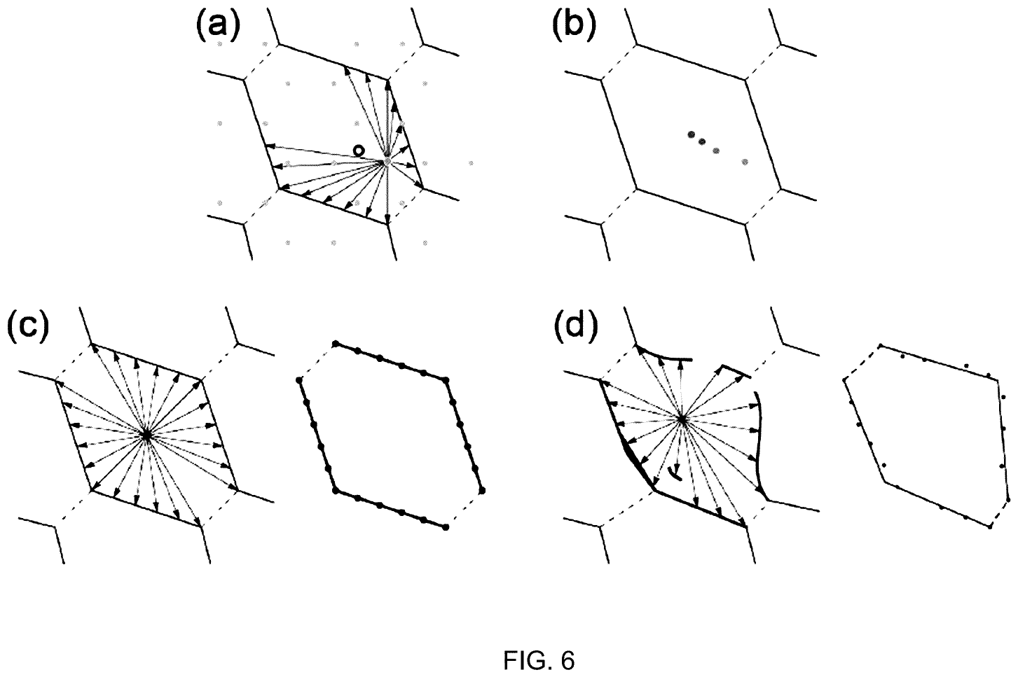

The model-building process starts with a selection of observation points from which the extended fingerprints will be measured. Ideally, each observation point should be located at the center of a polytopal domain. This desired arrangement of the centralized observation points is achieved through an iterative process. Starting with a selection of initial observation points on a dense hexagonal grid with points spaced every four pixels, an extended fingerprint is measured at each point and then fitted to rough star, shaped polygon models⁴¹. The centers of mass of the resulting models become new observation points, see FIG. 6(a). Iterating, this causes points to cluster at polygon centers in those regions where convex polygons are captured in the threshold map, see FIG. 6(b). In regions where the transition map has parallel or near, parallel lines, observation points do not cluster at center points, but rather along median lines. A simple process of pruning reduces the initial very large number of points to a relative few: if the distance between two observation points is less than the interior radius of either of the polygons they define, the two points are combined into a single point at the midpoint between them. The process continues until the locations of the observation points stabilize.

### Fingerprinting Charge Stability Diagram

Having found properly distributed observation points, the next step in the QD auto-annotator algorithm is to measure extended fingerprints at these points and build the final convex polygon models from each fingerprint, see FIG. 6(c). In noise, free settings, this is a completely straightforward process. However, the data binarization may give rise to three types of errors: (i) noise artifacts misidentified as indicators of charge transitions; (ii) transition lines with gaps when the thresholding detects no charge transition where a transition should be present; and (iii) stochastic imprecisions in transition line locations. The first two types of errors may severely hinder the model-building attempt and thus must be identified by the algorithm. In brief, some rays will strike a noise pixel before striking a transition line resulting in a ray that is too short, while others might miss a transition that should be present resulting in a ray that is too long. A dense sampling of rays allows relatively easy identification of individual or small clusters of ray anomalies, and additional checks for deviations from convexity allow the identification of larger groups of anomalous rays. All anomalous rays are removed from the analysis prior to modeling, see FIG. 6(d).

The imprecise positioning of the charge transitions is dealt with by using best, fit techniques to model extended fingerprint terminal points with line segments. While Gaussian best, fit methods are often used in such situations, modeling with a Gaussian cost function is unstable and even in reasonable cases may produce poor fits with data, see, e.g., the Simpson's paradox⁴²⁻⁴⁴. Instead, we use the much more stable normalized [symbol] Hausdorff distance to measure the fidelity of line segments to groupings of terminal points⁴⁵.

Definition 2 [Normalized Hausdorff distance] Let A and B be nonempty, finite sets of points within a metric space with metric ρ. The normalized [symbol] Hausdorff distance is

$${ρ}_{H} ( A , B ) = {( \frac{1}{2} 𝒟 {( A ; B )}^{2} + \frac{1}{2} 𝒟 {( B ; A )}^{2} )}^{\frac{1}{2}}$$

where [symbol] (A;B) is the [symbol] , deviation of A with respect to B defined as

$$𝒟 ( A ; B ) = {( \frac{1}{\vert A \vert diam {( A )}^{2}} {\sum }_{x ∈ A} dist {( x , B )}^{2} )}^{\frac{1}{2}} ,$$

with dist(x,B)=min{ρ(x,y)|y∈B},|A| denoting the cardinality of A, and diam(A )=sup{dist(x,y)|x,y∈A} denoting the diameter of A.

The set function [symbol] is not symmetric in A and B. Intuitively, [symbol] measures how far, in a root mean square sense, a typical point of A lies from the nearest point of B. For example, A⊆B implies [symbol] (A;B)=0 but says nothing about [symbol] (B; A). [symbol] is unitless and scale, invariant. The set function ρ_{H}, on the other hand, is symmetric in A and B and ρ_{H}(A,B)=0 if and only if A and B are the same set.

### Fitting and Modeling

The next phase of the model-building module involves fitting each of the extended fingerprints to a model. There are four kinds of polygons possible in a double, QD charge stability diagram: hexagons with two missing edges (representing mainly the DD state), pentagons with one missing edge (representing the SD_{L} and SD_{R}states), quadrilaterals (representing the SD_{C} state), and triangles (representing the ND state). Any missing edge in a model, should any exist, is called an aperture. This choice of geometric models is informed by the constant interaction model of double, QD systems described in the Labeling Double, dot states section. Each model is determined by a finite number of parameters that include the model's vertex points and the presence of apertures. Every choice of parameters determines a new polygonal model, which is then discretized. Letting this discretization be the set A and the fingerprint endpoints be the set B, we evaluate the [symbol] distance function ρ_{H}(A,B). Interpreting this as a cost function, we then search for model parameters that minimize this cost.

If the polygon has n vertices (for the double, QD device n is 4,5, or 6), then ρ_{H} must be minimized in a 2n dimensional configuration space. This search is carried out in two steps: a rough search and a fine search. In the rough search phase, all terminal points for a given extended fingerprint are ordered sequentially and each possible subset of n sequential points is used to build a polygon model. We then find the smallest value of ρ_{H} among the resulting models. For N terminal points, this means testing

$$( \begin{matrix}N \\ n\end{matrix} ) = \frac{N !}{( N - n ) ! n !}$$

possible models. When n is small and N»n this is larger than (N−n)ⁿ/n!, which can become computationally prohibitive for large N. Thus, we employ several mitigation strategies to reduce the number of models that need to be checked. For quadrilateral models, we bring the number of models to test down to about 2·(N/2)² by requiring that two of its vertices are diameter points of the fingerprint. When testing pentagonal or hexagonal models, we first search for gaps in the termination points and then force model apertures to span one or more of these gaps. If the number of gaps is M, this reduces the search to M·O(N²) models in the pentagonal case and

$$( \begin{matrix}M \\ 2\end{matrix} ) \cdot O ( {N}^{2} )$$

in the hexagonal case.

The second phase, the fine search, begins with the model selected in the rough search. Because the search space in the rough, fitting phase was restricted to only checking terminal points, it is possible that nearby points not included in the extended fingerprint might result in a substantially better fit. As noted earlier, ρ_{H} can be considered a function on 2n, dimensional space. To optimize the fit we employ the discrete gradient flow method on the gradient of ρ_{H} in this space. At each step in the flow the model's vertex points can move at most one pixel from their previous location. This constraint prevents oscillatory behavior. The number of steps necessary for convergence depends on the internal characteristics of the extended fingerprint, e.g., the size of the largest gaps between terminal points. In practice, we observe convergence in no more than 6 steps except for polygons in very noisy regions where this number can get larger. The fine search is computationally less demanding than the rough search, as gradients can be computed in polynomial time with respect to the number of polygon parameters. In our case, the computation cost scales as N·O(n) where N is the number of fingerprint terminal points. Since in our application n«N, this is significantly better than the O(N²) computation time for the rough search after improvements.

The result of the fine search is a polygon model for each extended fingerprint that locally minimizes the ρ_{H} cost function. The polygon creation process produces a polygonal tiling of the threshold map. Since the polygons are modeled independently, the resulting models may partly overlap one another and various, sized gaps between polygons may occur at this stage.

Such inaccuracies are most likely to occur in regions where the centralization algorithm is semi, stable, which happens when transition lines become roughly parallel (the CD area) and in the transitional area for high levels of noise. To fine, tune the proper tiling of the 2D map and to derive the final state labels we invoke methods of statistical inferencing.

### Statistical Inferencing Module

The polygon models provide an assemblage of discrete information about the underlying charge stability diagrams. From this information we gather statistics, isolate relevant features of the threshold map, and identify and filter noise that has come through the filtering mechanisms to this point.

### Noise Statistics and Filtering

The first relevant feature the QD auto-annotator collects statistics on is how well the polygon models fit their respective extended fingerprints. The fit is measured using the normalized [symbol] Hausdorff distance ρ_{H} discussed in the previous section⁴⁵.

Definition 3 [Model error at xₒ] Let [symbol] be an extended fingerprint from an observation point xₒ,A denote its set of terminal points and B denote the set of all points on its polygon model except those that lie on any aperture segments. We define the model error at an observation point xₒ as [symbol] (xₒ)=ρ_{H}(A,B).

After the polygon around each observation point xₒ receives the error score [symbol] (xₒ), the scores are analyzed collectively to determine their statistical spread. Empirically, low, noise scans have model errors tightly clustered near 0, see FIG. 6(c), while high, noise scans show large deviations, see FIG. 6(d). If a polygon model's [symbol] (xₒ) lies more than 2 standard deviations away from the mean, it is discarded. This creates gaps in the tiling of the threshold map which are overcome through statistical methods.

### Establishing Directionality: Heat Flow Clustering

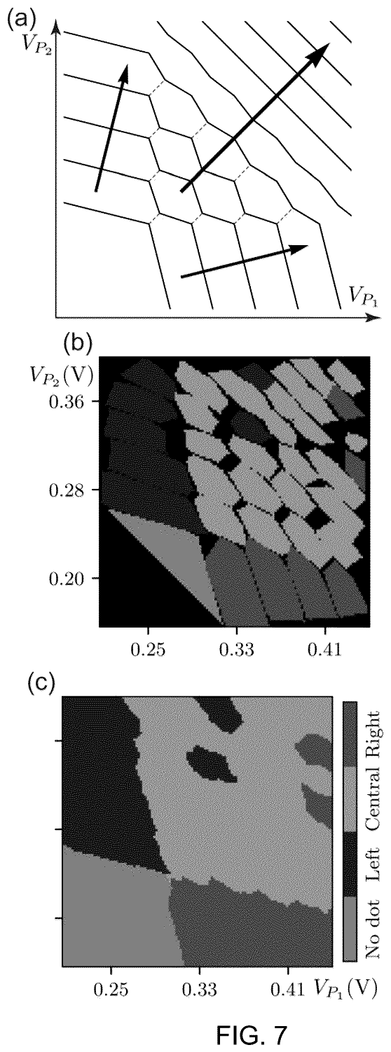

After the polygons have been created and filtered based on the fit quality, the remaining models are used to create the gross characteristics of the threshold map. Polygon models must be clustered by their orientation into the scan's dominant directions, which must also be detected. For a double, QD there are three dominant directions: left, right, and center corresponding to the left, right, and combined double and central QD state, respectively; see FIG. 7(a). The QD auto-annotator does not assume the existence of all directions in a given scan. Rather, the system is designed to automatically recognize which directions are present and which states need to be characterized.

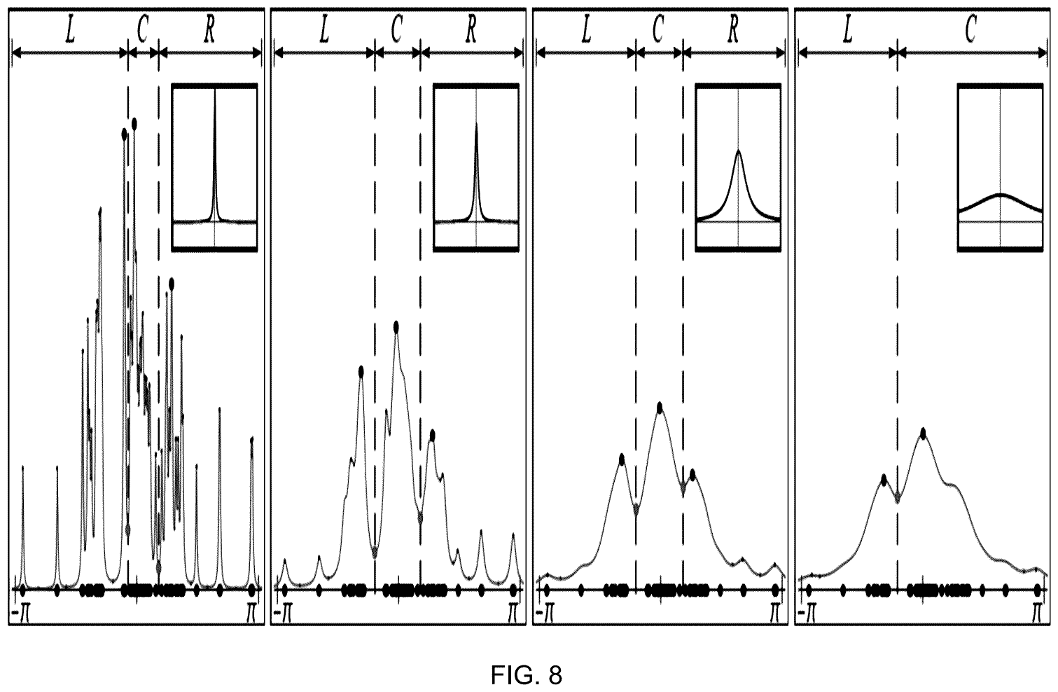

The dominant directions present in the threshold map are determined through clustering of polygon orientations defined by the unit normal to the median line through the model. The clustering is carried out by a custom heat flow clustering algorithm⁴⁶ rooted in the idea of persistence. The algorithm expands on techniques from the differencing potential method⁴⁷, in which a smooth kernel is chosen and convolved with the point locations, to produce a smooth potential field and the peaks of the potential field are then taken to be cluster centers, see FIG. 8. The challenge with the differencing potential method is in choosing a proper kernel since an effective choice requires foreknowledge of expected cluster widths as well as rough parity in the number of points within each cluster. Since this information is not available ahead of time, rather than relying on a single kernel, the heat flow clustering algorithm uses an ensemble of them. The idea is that intrinsic features of the data will manifest persistently through many kernel choices.

The algorithm works by selecting a static kernel k(x) that resembles a Gaussian, and then scaling parabolically to obtain the time-dependent function K(x,t)=k(x/\sqrt{t})/\sqrt{t}; this parabolic scaling causes K to imitate the classic 1D heat flow, particularly in that the kernel starts from nearly a δ, function when t is small and spreads through time while its L¹, norm remains constant. A selection of discrete times {t₁, . . . , t_{N}} is chosen and a clustering method, similar to a 1D version of the differencing potential clustering 47, is performed at each time tᵢ. The times tᵢ, . . . , t_{N} are chosen so that the smallest standard deviation and largest standard deviation have no chance of accurately resolving clusters. Then the tᵢ are evenly spaced between, with N=15. Final cluster selections are arrived at when each point is assigned the cluster it most persistently belongs to. The heat flow clustering algorithm results in as few as one and as many as three cluster points which become the one, two, or three characteristic directions.

### Global State Determination Module

The final step of the QD auto-annotator is to create the domain decomposition based on the individual polygon identification and the statistical grouping. At this point, there may be errors or misidentifications in the polygon models, and the models themselves may overlap or have gaps between them, see FIG. 7(b). The fingerprinting architecture, used in the model-building module to model polygons, has the computationally valuable ability to easily create convex hulls and compute areas. In the global state determination module of the QD auto-annotator fingerprinting is used again, this time to model the global domains rather than individual polygons. The global state determination is performed in two phases: first the QD auto-annotator assigns each polygon to one of three orientation-based domains (left, central, and right). Then, in the second phase, the central domain is split into DD and SD_{C} states.

### Remodeling

The polygon models obtained at this point might overlap and the overall tiling of the threshold map might contain gaps, as depicted in FIG. 7(b). Before the global state labels can be assigned the overlaps must be resolved and any existing gaps filled in, with each point in the scan assigned to a unique polygon. To eliminate the overlaps, the QD auto-annotator assigned each point claimed by two or more polygons to the nearest polygon center, as long as the direct line between the point and that center does not cross a transition line. To remove the gaps between polygons, the territory each polygon inhabits is expanded until all gaps are filled. The expansion process is carried out in two stages using a custom expansion method.

In the first stage, unassigned pixels adjacent to a classified polygon get absorbed by it as long as the line between the pixel and the centroid of the polygon it attaches to does not cross a transition line. This process is repeated to exhaustion, with the territory claimed by each polygon growing at a rate of at most one, pixel layer at each stage. Pixels belonging to transition lines in the threshold map are not considered at this stage. In the second run, the same process is performed, this time ignoring the transition lines and performing the expansion method without restriction until every pixel in the image is assigned to a polygon. For the ND state, the filling, in is carried out based on algebraic relation derived for the two short edges of the triangle where all points below those edges are automatically assigned to the ND class.

In the resulting filled, in map each pixel is classified as belonging to the ND, SD_{L}, SD_{C}, or SD_{R} state, though some polygons might at this point be misclassified, see FIG. 7(c). Moreover, at this stage of the analysis, the DD domain remains within the SD_{C} domain and will be separately identified later. The filled, in map is used to create the 4, state domain decomposition into ND, SD_{L}, SD_{C}, and SD_{R} states.

### Labeling Single-Dot States

The QD auto-annotator classifies polygons into left, center, and right classes based on their orientations. However, due to fingerprinting and fitting errors as well as any number of noise factors and boundary effects, some polygons might be misclassified, as depicted in FIG. 7(c). To correct potential misclassifications, the QD auto-annotator performs are, examination of all polygons within each class, with the underlying expectation being that the left, center, and right, class assigned polygons should mostly be contiguously grouped on the left, center, and right side of the scan, respectively. Individually misclassified polygons will likely be haphazardly distributed throughout the scan.

The re, examination is carried out on a per, class basis for the left and right orientation. For each class, a 0, or, 1 map is created, with 1 indicating a pixel attached to the class under consideration and 0 indicating all alternative classes. To identify the most probable region of the scan to be assigned as the relevant domain, the algorithm first creates a convex hull of each contiguous grouping for a given class, then the area of each hull is computed and the region with the largest area is selected. Lastly, the selected convex hull is modeled with its own polygon using the same fingerprinting techniques as were used to create the smaller polygon models. This may result in assigning the fingerprint, modeled polygons to more than one domain. Points that belong to such multiple, domain polygons are used to determine the gradual transition between domains.

### Labeling Double-Dot States

The center, dot region must be divided into DD and SD_{C} domains. However, the polygon orientation is insufficient to differentiate between the SD_{C} and DD states. Rather, the QD auto-annotator employs physical principles to make this determination. The transition between the SD_{C} and DD states is not sharp, so to label the scan we must be able to measure a grading between the states.

In the SD_{C} state, the valence electrons are not localized on either QD but form a pair that acts as an SD. In the DD state, in contrast, the electrons interact, but each is on a distinct QD³⁸. In the charge stability diagram, the nature of the electron, electron coupling of the (m,n) state is manifest by the shape of the (m,n) polygonal cell. We interpret these shapes using the constant interaction model for coupled QDs^{36,38}. A quadrilateral cell indicates there is very little electrostatic coupling between the QDs: the central barrier is so high that the electrons are nearly non, interacting [see inset in FIG. 4(a)]. At the other end of the spectrum, indistinct cells indicate the electrons have merged into a charge, position multiplet: the barrier is so low that the electrons are no longer spatially separate. Hexagonal cell geometry indicates the barrier is large enough that the electrons are (mostly) spatially localized, but small enough that tunneling interactions are possible.

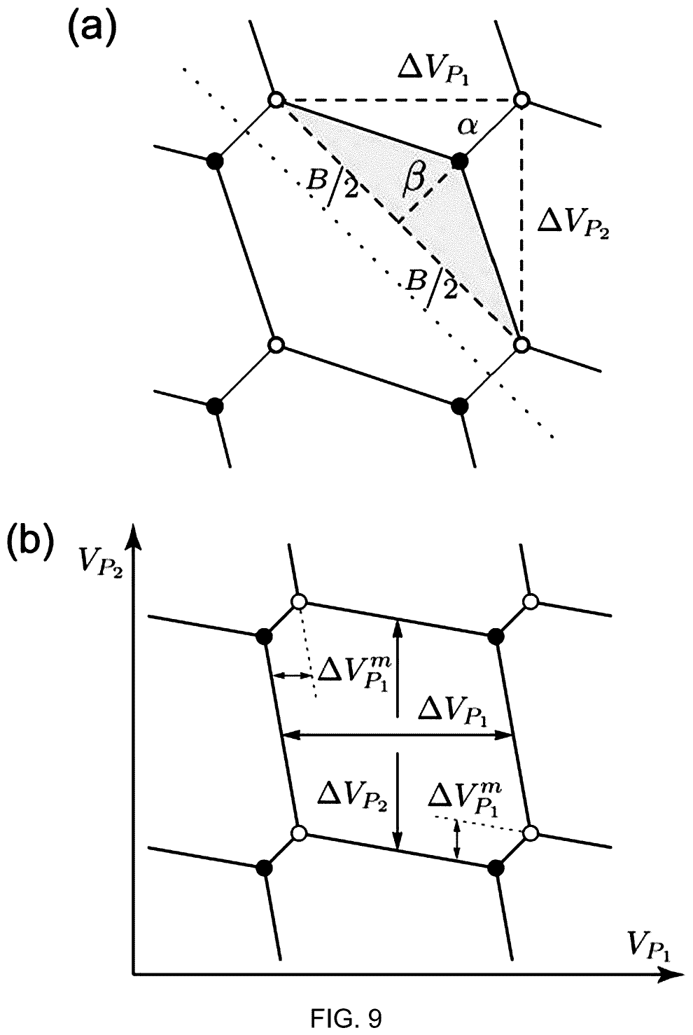

To create a physically meaningful quantitative measure of the hexagon-ness of a cell, we divide each cell along its centerline [the dotted line in FIG. 9(a)] into an upper and lower cell (the regions above and below the dotted line, respectively). Then, we define the cell roof as the region above the dashed line of length B in the upper cell in FIG. 9(a) and the cell floor as a corresponding region in the lower cell. After the polygon models have been built (see the Model, building module section), the following ratios are easily calculated:

$$U = \frac{area ( roof )}{area ( upper cell )} and L = \frac{area ( floor )}{area ( lower cell )}$$

We interpret these geometric ratios in terms of the constant capacitance model, with

$$B = {[ {( {ΔV}_{{P}_{1}} )}^{2} + {( {ΔV}_{{P}_{2}} )}^{2} ]}^{\frac{1}{2}} , α = {\frac{1}{2} [ {( {ΔV}_{{P}_{1}}^{m} )}^{2} + {( {ΔV}_{{P}_{2}}^{m} )}^{2} ]}^{\frac{1}{2}} , β = - α + \frac{{ΔV}_{{P}_{1}} {ΔV}_{{P}_{2}}}{B} , and α , β ∈ [ 0 , \frac{1}{2} B ] ,$$

where ΔV_{P}_{ᵢ} and

$${ΔV}_{{P}_{2}}^{m}$$

denote the spacing between the charge transitions, see FIG. 9(b).

While in the idealized constant capacitance model U=L, in real, world devices, these ratios are equal only if device characteristics, such as cross, talk and stray capacitances, vary negligibly within the dynamic ranges of the plunger voltages. As this, in general, is not true, the values of U and L are expected to be different and are computed separately as

$$U , L = \frac{\frac{1}{2} β B}{\frac{1}{2} β B + \frac{1}{2} αB} = 1 - \frac{1}{2} \frac{\sqrt{{( {ΔV}_{{P}_{1}}^{m} )}^{2} + {( {ΔV}_{{P}_{2}}^{m} )}^{2}} \sqrt{{( {ΔV}_{{P}_{1}} )}^{2} + {( {ΔV}_{{P}_{2}} )}^{2}}}{{ΔV}_{{P}_{1}} {ΔV}_{{P}_{2}}}$$

In practice, the values of

$${ΔV}_{{P}_{1}}^{m} , {ΔV}_{{P}_{2}}^{m}$$

change with the absolute values of the gate voltages V_{P}_{₁} and V_{P}_{₂} and can vary substantially even within the same hexagon giving U and L measurably different values. In special cases, when

$${ΔV}_{{P}_{1}} \approx Δ$$

$${V}_{{P}_{2}} ≡ {ΔV}_{P} and {ΔV}_{{P}_{1}}^{m} \approx {ΔV}_{{P}_{2}}^{m} ≡ {ΔV}_{P}^{m} ,$$

we can simplify Eq. (4) as

$$U \approx 1 - \frac{{ΔV}_{P}^{m}}{{ΔV}_{P}} \approx 1 - \frac{{C}_{M}}{C} and L \approx 1 - \frac{{ΔV}_{P}^{m}}{{ΔV}_{P}} \approx 1 - \frac{{C}_{M}}{C}$$

The range is

$${ΔV}_{P}^{m} ∈ [ 0 , {ΔV}_{g} ]$$

so that U,L ∈[0,1] with 0 indicating a completely joined SD, 1 indicating fully decoupled DD, and U,L ∈(0,1) indicating intermediate states of electron, electron coupling.

Although a quantitative grading between DD and SD states can be read off geometrically from the charge stability diagram, to give each polygon a specific label, a choice must be made as to appropriate cutoffs. Exactly where these cutoffs are located will depend to some extent on the application. The QD auto-annotator is fully customizable and can be adjusted depending on the research needs. From the area ratio we create the quantitative hexagon-ness score [symbol] for each polygon

$$ℋ = \{ \begin{matrix}\frac{1}{0.8} ( U + L ) , & if 0 \leq \frac{1}{2} ( U + L ) \leq 0.4 \\ 1 , & if 0.4 < \frac{1}{2} ( U + L ) \leq 1\end{matrix}$$

The [symbol] can be interpreted as the probability that a given polygon represents a DD versus SD state.

### The Final Domain Decomposition

The final domain decomposition involves the assignment of a vector, valued function from the pixel location Vᵢ=(xᵢ,yᵢ) within the charge stability diagram to a probability vector p(Vᵢ)=(P_{ND},P_{SD}_{_{L}},P_{SD}_{_{C}},P_{SD}_{_{R}},P_{DD}) such that each component on vector p(Vᵢ) is non, negative and p_{ND}+P_{SD}_{_{L}}+P_{SD}_{_{C}}+P_{SD}_{_{R}}+P_{DD}=1^{17,19}. The components of the vector p(Vᵢ) represent the probability that the point Vᵢ belongs to one of the five domains: p_{ND} is the probability the point Vᵢ is in the ND region, the P_{SD}_{_{L}}, P_{SD}_{_{C}}, and P_{SD}_{_{R}} probabilities that point Vᵢ is in the left, center, and right, SD region, respectively, and p_{DD} is the probability that point Vᵢ is in the DD domain. The probabilities are assigned in three distinct phases: an initial sharp 4, domain probability assignment discussed in the Labeling single-dot states section (double-dot assignments not created yet), then the insertion of the double-dot graded probabilities based on the hexagon-ness score described in section Labeling double-dot states section, and finally the creation of a probability grading between the adjacent domains.

The initial 4, domain decomposition assigns to each point a state vector p⁽⁴⁾(Vᵢ)=(P_{ND},P_{SD}_{_{L}},P_{SD}_{_{C}},P_{SD}_{_{R}},0) where exactly one of p_{ND},P_{SD}_{_{L}},P_{SD}_{_{C}}, and P_{SD}_{_{R}} is 1 and the others four components are 0. After the polygonal modeling of the left, right, and ND domains described in the Labeling single-dot states section, every pixel is in a definite ND, LD, CD, or RD domain. However, the small fingerprint, defined polygons lying near the domain boundaries might overlap with two or more domains. When assigning the probability vectors, points inside polygons that were partially absorbed by one of the adjacent domains are resigned back to the original class based on the region its center, point lies within.

The second stage alters the polygons in the CD region by assigning to each polygon its DD probability. Using the score [symbol] given in Eq. (6), the state vector for points within this region is updated as p⁽⁵⁾(Vᵢ)=(0,0,1− [symbol] ,0, [symbol] ). Outside of this region the state vector p⁽⁵⁾(Vᵢ)=p⁽⁴⁾(Vᵢ), with exactly one of p_{ND}, P_{SD}_{_{L}}, and P_{SD}_{_{R}} equal 1 and the other components equal 0.

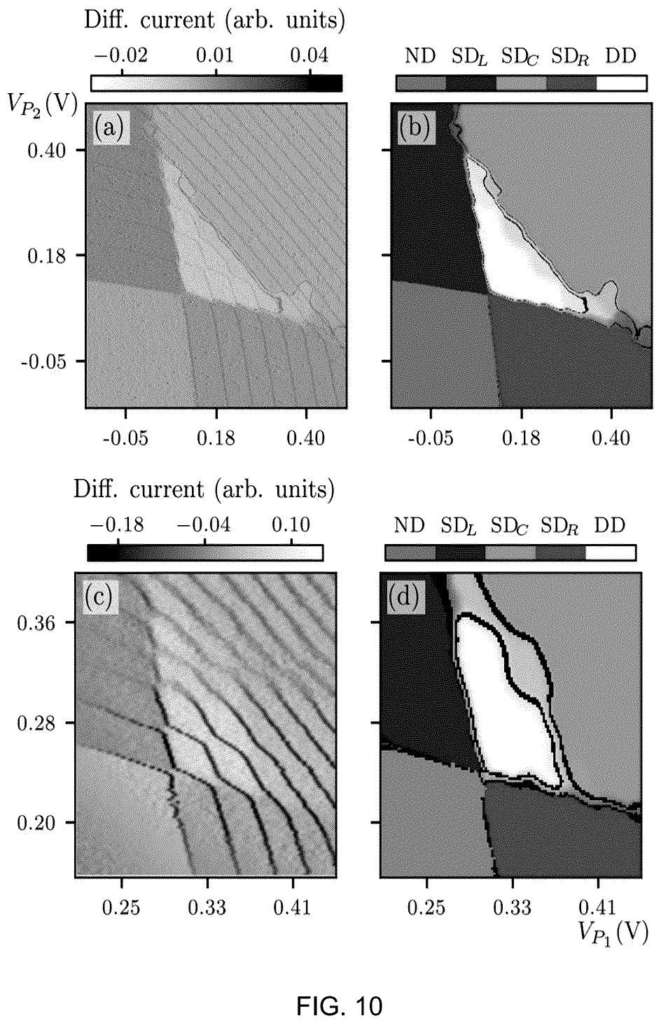

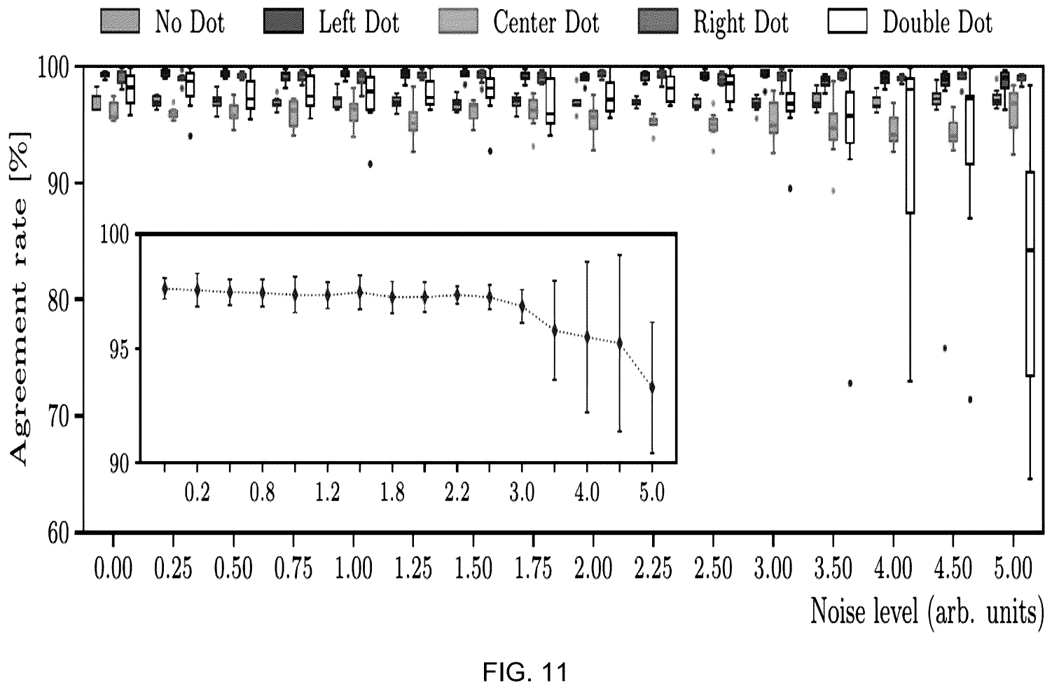

Finally, in the third stage, the state vectors are probabilistically interpolated between the adjacent domains. The assignment of individual polygons to each state makes an artificially sharp and ridged boundary between the CD and LD or RD domains, see FIG. 7(c). At the same time, just as there is no completely sharp boundary between the CD and DD domains, there is no completely sharp distinction between the CD and LD state or between the CD and RD state. The probability grading between the outer LD and RD domains and the laying between them CD and DD domains is determined geometrically. To do this, we observe that the individually labeled polygons drift into neighboring regions, as visible in FIG. 7(c), and we measure how far into that region they drift. We take these distances to be a standard deviation of the uncertainty of the region boundary. Then we convolve the 5, vector, with a local kernel having the width of this deviation. The result is a probability vector p(Vᵢ) that grades among the five regions based on the uncertainty in the boundary location. FIGS. 11(a) and 8 (c) show the final domain decomposition for a sample noisy simulated device shown in FIG. 5(a) and a sample experimental scan shown in FIG. 5(d), respectively. Regions with confidence in the dominant label of at least 70% are represented as ringed areas in FIG. 10(b) for the simulated data and in FIG. 10(d) for the experimental scan. The gradual change in the color indicates transitional labeling.

### Technical Validation

In simulated settings, noise and sensor artifacts can be modeled and adjusted in a controlled fashion³¹. This allows for systematic validation of the QD auto-annotator performance for an increasingly degrading data quality. To validate the auto-annotator, we use a set of 7 qualitatively distinct simulated double, QD devices with varying levels of noise^{20,25}. The noise levels used in these tests are varied around a reference level extracted from the experimental data²⁰. For simplicity, the reference noise is denoted as 1.00. For each simulated device we use 16 noise levels ranging from 0.00 (noiseless data) to 5.00. In addition, we test the performance of the QD auto-annotator on a set of 9 large experimental scans from the QFlow 2.0 dataset²⁹.

Validation with Simulated Data

Using the ground truth labels assigned at a pixel level during simulations and the QD auto-annotator labels we can quantify both the overall per, device agreement between labels as well as the per-class performance. The ground truth labels for the simulated data, [symbol] (Vᵢ), are represented as one, hot vectors, with the hot component indicating the assigned state. The QD auto-annotator algorithm provides a map where each pixel is assigned a probability vector p(Vᵢ). To quantify the overall performance, we compare these two vectors at each point within each simulated scan. Pixels for which the QD auto-annotator shows an agreement with ground truth at least 70% are flagged as correct. Otherwise, they get an incorrect flag. We observe an overall state assignment agreement at around 97% when averaged over all devices for noise levels up to 3.00, see the inset in FIG. 11. Once the noise level surpasses 3.00, the agreement deteriorates slightly to 95.6(3.3)% at noise level 4.00 and 93.3(2.8) % at noise level 5.00. For comparison, the performance of a QD charge tuning algorithm proposed recently²⁰ begins to decline at noise level 2.00.

We then compute the proportion of correct pixel assignments to the total number of pixels in each of the five domain regions, as determined by the ground truth labels. FIG. 11 shows the performance of the QD auto-annotator on a per, domain basis for each noise level for the 7 simulated devices. The ND, SD_{L}, and SD_{R} state identifications remain almost perfectly robust up to the highest considered noise level. The CD_{L} state shows a slight decay in performance at higher noise levels (at around noise level 3.00). The DD state assignment is the most fragile and breaks down once the simulated noise levels surpass 3.50.

The statistical determination, error mitigation, and data redundancy ensure stable state assignments for ND, SD_{L}, and SD_{R}. Since the domains in the charge stability diagrams decomposition are complementary, the high and consistent performance in classifying these three domains naturally translates on a comparable performance in determining the combined SD_{R} and DD domain (the central orientation region). The QD auto-annotator's sub, statistical boundary determination between SD_{R} and DD domains results in performance degradation at higher noise levels.

The boundary between the SD_{R} and DD regions is determined by a series of measurements on individual polygons quantifying their hexagon-ness, see Eq. (4) and Eq. (6). Because this process relies on measurements taken on individual polygons, it contains no redundancy or statistical error, checking which makes the SD_{R} and DD state assignment more sensitive to noise. However, despite this limitation, the SD_{R} and DD state assignments remain quite robust up to a fairly high level of noise, as can be seen in FIG. 11.

Validation with Experimental Data

For the experimental data, the ground truth labels are not available. It is thus not possible to perform large-scale quantitative validation of the QD auto-annotator performance. Thus, when assessing the outputs of the algorithm for experimental data we focus on the qualitative features resulting from the assigned labels. In particular, we focus on the overall locations of the individual states within the 2D configuration space, such as the ND state in the bottom left corner or the SD_{L} and SD_{R} states on the top, left and bottom, right sides, respectively. We also consider the agreement between the charge transition lines geometry, e.g., horizontal or vertical parallel lines, and the assigned global state label, e.g., the SD_{R} or SD_{L} state. Finally, we look at the correctness of the transitional regions, i.e., DD state blending into SD_{L} as V_{P}_{₁} (V) decreases, into SD_{R} as V_{P}_{₂}(V) decreases, and into SD_{C} as V_{P}_{₁}(V) and V_{P}_{₂}(V) increase.

The output of the QD auto-annotator is a 2D map with a label at each point indicating the probabilistic assignment of the five possible states. A sample probabilistic domain decomposition for the experimental scan shown in FIG. 5(d) is depicted in FIG. 10(c). To ease the analysis, the state labels are shown overlaying the original scan. FIG. 10 highlights in the configuration space regions where the label confidence surpasses 70% as well as regions where the labels indicate a transition between states (i.e., all components of the probability vector p(Vᵢ) are less than 0.7). A visual inspection of these two images confirms a high level of agreement between the QD auto-annotator assigned labels and the human interaction. To further validate the quality of the domain decomposition returned by the QD auto-annotator we consulted with two external experts, one working in academia and one in the industry. Both experts are experimentalists with long experience in the semiconductor QDs domain. The received feedback further confirms the high level of agreement between the automatically generated labels and how the experts thought they would manually label the data.

### Data Records

The QF low 2.0 dataset²⁹ is hosted and freely available from NIST, a bureau of the US Department of Commerce. Data representing the seven simulated QD devices as well as labels for all experimental scans supporting the findings of this study are added to the database.

The reference (i.e., noiseless) simulated test QD devices used in this work are stored as separate NumPy files in the compressed simulated\sim_test folder. The name of each simulated file indicates the simulated device configuration and the noise level, e.g., 10nmGatePitch_SmallSlopeScreening_NoiseLevel0.20.npy. are named as exp_large_xx.npy, where xx are consecutive numbers between 0 and 12. The taxonomy of the files is presented in Table 1. The Item field indicates the dictionary key, the Description field indicates the dictionary value, and the Noiseless data, Noisy data, and Experimental data columns indicate whether or not a given item exists for a given data type.

### Usage Notes

The QD auto-annotator is a critical step in a proposed public, private, academic partnership intended to produce a data, sharing system for the QD community²⁴. The lack of such sharing partnerships has been recognized as a hindrance to development within this field. Establishing a comprehensive and reliable reference database of labeled experimental data is essential for the development of automation tools for the characterization and control of QD devices. The QD auto-annotator is the first step on the path to establishing such a standardized database.

The QD auto-annotator enables systematic processing and labeling of experimentally acquired charge stability diagrams. The validation of the algorithm's performance using simulated data confirms that it can reliably label data with noise levels surpassing what is typically observed in experiments. However, as we discussed in the Data preparation module section, the QD auto-annotator requires a binarized version of the charge stability diagram as input. At the same time, the thresholding module relies at present on human input which presents a bottleneck to large-scale deployment of the QD auto-annotator. While we are actively developing an algorithm for fully automated binarization of the experimental charge stability diagrams, this effort is impeded by a lack of openly available moderate, and poor, quality experimental data given the still prevalent practice in the QD community to “make data available only upon “reasonable request,” or to not share it at all”²⁴.

The Table lists the taxonomy of the data files added to the QFlow 2.0 dataset. The first column identifies each item in the respective files (expressed as keys in the relevant Python dictionary). The second column provides the description of each item. The last three columns indicate whether or not a given item exists for a given data type.

TABLE

| Item | Description |
|---|---|
| sensor | Simulated data: The output of the charge sensor evaluated as the |
| | Coulomb potential at the sensor location (with simulated noise |
| | added if in the noisy sensor data). Experimental data: the charge |
| | sensor data (in amperes). |
| V_P1_vec | A voltage range for the first plunger (V_{P}_{₁}). |
| V_P2_vec | A voltage range for the second plunger (V_{P}_{₂}). |
| state | The label determining the state of the device at each point, |
| | distinguishing between ND(0), SD_{L}(0.5), SD_{C}(1), SD_{R} (1.5), and |
| | a DD (2) |
| charge | The information about the number of charges on each QD (with a |
| | default value 0 for ND state). |
| noise_level | The level of the simulated noise. |
| mask | The binary threshold map. |
| qda2_vec | The probabilistic state labels returned by the QD auto-annotator at |
| | each point. |
| conf_ring | The 70% confidence ring indication the dominant state labels. |

The success of the current project is aimed at providing concrete, mutual benefits to data sharing. The value, added proposition, described here, is the automatic processing and labeling of datasets that the QD auto-annotator makes possible at scale. Once the automated thresholding module is completed, a simple, web, based interface for uploading and processing QD data using the QD auto-annotator will become available. In the meantime, access to the QD auto-annotator will be restricted to users interested in sharing their data to aid the development of data binarization methods. In addition, all labeled data will be systematically added to the QFlow 2.0²⁹ database.

### Code Availability

The dataset used in this work, QF low 2.0²⁹, is available from NIST, a bureau of the US Department of Commerce. The size of the datasets is over 13 GB (compressed), which includes 13.4 GB of simulated data and 15.8 MB of experimental data. The QFlow2.0 is provided subject to open, access licensing for researchers globally. The code used to generate the QFlow 2.0 is being prepared for public release together with instructions for reproduction of the dataset⁴⁸. An access to the functionality provided by the QD auto-annotator will be provided via a web, based interface. In addition, all new data analyzed via the web, based interface will be added to the QFlow 2.0 database.

This Example includes citation to scientific literature, listed below and indicated by the use of superscripts in the text of the Example. This inclusion of the citations and the cited scientific literature are not to be construed as an admission that such scientific literature constitutes prior art or is otherwise available as prior art against the claimed invention under any patent statute or jurisprudence. Further, any citation to documents, scientific articles, or publications is solely for the purpose of providing a general historical context and is not an admission of anticipation or obviousness of the claimed subject matter. Each reference cited in the following list is incorporated herein by reference in its entirety.
1. Zwanenburg, F. A. et al. Silicon quantum electronics. Rev. Mod. Phys. 85, 961, 1019, 10.1103/RevModPhys.85.961 (2013).
2. Petta, J. R. et al. Coherent manipulation of coupled electron spins in semiconductor quantum dots. Science 309, 2180, 2184, 10.1126/science. 1116955 (2005).
3. Koppens, F. H. L. et al. Driven coherent oscillations of a single electron spin in a quantum dot. Nature 442, 766, 771, 10.1038/nature05065 (2006).
4. Medford, J. et al. Quantum, dot, based resonant exchange qubit. Phys. Rev. Lett. 111, 050501, 10.1103/PhysRevLett.111. 050501 (2013).
5. Kim, D. et al. High, fidelity resonant gating of a silicon, based quantum dot hybrid qubit. npj Quantum Inf. 1, 15004 (2015).
6. Barthel, C., Reilly, D. J., Marcus, C. M., Hanson, M. P. & Gossard, A. C. Rapid single, shot measurement of a singlet, triplet qubit. Phys. Rev. Lett. 103, 160503 (2009).
7. Veldhorst, M. et al. An addressable quantum dot qubit with fault, tolerant control, fidelity. Nat. Nanotechnol. 9, 981, 985 (2014).
8. Kawakami, E. et al. Electrical control of a long, lived spin qubit in a Si/SiGe quantum dot. Nat. Nanotechnol. 9, 666, 670 (2014).
9. Yoneda, J. et al. A quantum, dot spin qubit with coherence limited by charge noise and fidelity higher than 99.9%. Nature Nanotechnology 13, 102, 106, 10.1038/s41565, 017, 0014, x (2018).
10. Vandersypen, L. M. K. & Eriksson, M. A. Quantum computing with semiconductor spins. Phys. Today 72, 38, 45, doi:10.1063/PT.3.4270 (2019).
11. Chanrion, E. et al. Charge detection in an array of CMOS quantum dots. Phys. Rev. Appl. 14, 024066, 10.1103/PhysRevApplied.14.024066 (2020).
12. Zwerver, A. M. J. et al. Qubits made by advanced semiconductor manufacturing. Nat. Electron. 5, 184, 190, 10.1038/s41928, 022, 00727, 9 (2022).
13. Zwolak, J. P. & Taylor, J. M. Colloquium: Advances in automation of quantum dot devices control. Rev. Mod. Phys. 95, 011006, 10.1103/RevModPhys.95.011006 (2023).
14. Darulove, J. et al. Autonomous tuning and charge, state detection of gate, defined quantum dots. Phys. Rev. Appl. 13, 054005, 10.1103/PhysRevApplied.13.054005 (2020).
15. Baart, T. A., Eendebak, P. T., Reichl, C., Wegscheider, W. & Vandersypen, L. M. K. Computer, automated tuning of semiconductor double quantum dots into the single, electron regime. Appl. Phys. Lett. 108, 213104, 10.1063/1.4952624 (2016).
16. Durrer, R. et al. Automated tuning of double quantum dots into specific charge states using neural networks. Phys. Rev. Appl. 13, 054019, 10.1103/PhysRevApplied.13.054019 (2020).
17. Kalantre, S. S. et al. Machine learning techniques for state recognition and auto, tuning in quantum dots. npj Quantum Inf. 5, 1, 10, 10.1038/s41534, 018, 0118, 7 (2019).
18. Zwolak, J. P. et al. Autotuning of double-dot devices in situ with machine learning. Phys. Rev. Appl. 13, 034075, 10.1103/PhysRevApplied.13.034075 (2020).
19. Zwolak, J. P. et al. Ray, based framework for state identification in quantum dot devices. PRX Quantum 2, 020335, 10.1103/PRXQuantum.2.020335 (2021).
20. Ziegler, J. et al. Tuning arrays with rays: Physics, informed tuning of quantum dot charge states. Phys. Rev. Appl. 20, 034067, 10.1103/PhysRevApplied.20.034067 (2023).
21. Czischek, S. et al. Miniaturizing neural networks for charge state autotuning in quantum dots. Mach. Learn.: Sci. Technol. 3, 015001, 10.1088/2632, 2153/ac34db (2022).
22. Lapointe, Major, M. et al. Algorithm for automated tuning of a quantum dot into the single, electron regime. Phys. Rev. B 102, 085301, 10.1103/PhysRevB.102.085301 (2020).
23. Botzem, T. et al. Tuning Methods for Semiconductor Spin Qubits. Phys. Rev. Appl. 10, 054026, 10.1103/PhysRevApplied. 10.054026 (2018).
24. Zwolak, J. P. et al. Data needs and challenges of quantum dot devices automation: Workshop report. (in preparation).
25. Ziegler, J. et al. Automated extraction of capacitive coupling for quantum dot systems. Phys. Rev. Appl. 19, 054077, 10.1103/PhysRevApplied.19.054077 (2023).
26. Deng, L. The mnist database of handwritten digit images for machine learning research. IEEE Signal Processing Magazine 29, 141, 142 (2012).
27. Krizhevsky, A., Hinton, G. et al. Learning multiple layers of features from tiny images (2009). Toronto, ON, Canada.
28. Perrier, E., Youssry, A. & Ferrie, C. QDataSet, quantum datasets for machine learning. Sci. Data 9, 582, 10.1038/s41597, 022, 01639, 1 (2022).
29. National Institute of Standards and Technology. Qflow 2.0: Quantum dot data for machine learning. Database: data.nist.gov, https://doi.org/10.18434/T4/1423788 (2022).
30. Zwolak, J. P., Kalantre, S. S., Wu, X., Ragole, S. & Taylor, J. M. QFlow lite dataset: A machine learning approach to the charge states in quantum dot experiments. PLoS ONE 13, e0205844, 10.1371/journal.pone. 0205844 (2018).
31. Ziegler, J. et al. Toward robust autotuning of noisy quantum dot devices. Phys. Rev. Appl. 17, 024069, 10.1103/PhysRevApplied.17.024069 (2022).
32. White House Office of Science and Technology Policy. Biden, harris administration announces new actions to advance open and equitable research. Fact Sheet, White House, Washington, DC (2023). Published 2023, 01, 11.
33. Existence and Use of Large Datasets To Address Research Questions for Characterization and Autonomous Tuning of Semiconductor Quantum Dot Devices. 88 Fed. Reg. 22409 (Jul. 18, 2023). Accessed: 2023, 10, 17.
34. National Institute of Standards and Technology. Workshop on advances in automation of quantum dot devices control (2023).
35. Hanson, R., Kouwenhoven, L. P., Petta, J. R., Tarucha, S. & Vandersypen, L. M. K. Spins in few, electron quantum dots. Rev. Mod. Phys. 79, 1217, 1265, 10.1103/RevModPhys. 79.1217 (2007).
36. Beenakker, C. W. J. Theory of coulomb, blockade oscillations in the conductance of a quantum dot. Phys. Rev. B 44, 1646, 1656, 10.1103/PhysRevB.44.1646 (1991).
37. Schröer, D. et al. Electrostatically defined serial triple quantum dot charged with few electrons. Phys. Rev. B 76, 075306, 10.1103/PhysRevB.76.075306 (2007).
38. van der Wiel, W. G. et al. Electron transport through double quantum dots. Rev. Mod. Phys. 75, 1, 22, 10.1103/RevModPhys. 75.1 (2002).
39. Zwolak, J. P., Kalantre, S. S., McJunkin, T., Weber, B. J. & Taylor, J. M. Ray, based classification framework for highdimensional data. In Third Workshop on Machine Learning and the Physical Sciences (NeurIPS 2020), 1, 7 (Vancouver, Canada, 2020). ArXiv:2010.00500.
40. Weber, B. J., Kalantre, S. S., McJunkin, T., Taylor, J. M. & Zwolak, J. P. Theoretical bounds on data requirements for the ray, based classification. SN Comput. Sci. 3, 57, 10.1007/s42979, 021, 00921, 0 (2022).
41. Singer, I. A. & Thorpe, J. A. Lecture Notes on Elementary Topology and Geometry. Undergraduate Texts in Mathematics (Springer, Verlag, New York, Heidelberg, Berlin, 1967).
42. Simpson, E. H. The interpretation of interaction in contingency tables. J. R. Stat. Soc. Series B Stat. Methodol. 13, 238, 241 (1951).
43. Yule, G. U. Notes on the theory of association of attributes in statistics. Biometrika 2, 121, 134, 10.1093/biomet/2.2.121 (1903).
44. Pearson Karl, L. & Leslie, B. Genetic (reproductive) selection: inheritance of fertility in man, and of fecundity in thoroughbred racehorses. Philos. Trans. R. Soc. Lond. Ser. A 192, 257, 330, 10.1098/rsta. 1899.0006 (1899).
45. Evans, L. C. & Gariepy, R. F. Measure theory and fine properties of functions (CRC press, 2015).
46. Weber, B. J. Information stability in the heat flow clustering. (in preparation).
47. Wang, S. et al. Clustering by differencing potential of data field. Computing 100, 403, 419 (2018).
48. Buterakos, D. i. Qflowsim: The quantum dot device simulator. (in preparation).

The processes described herein may be embodied in, and fully automated via, software code modules executed by a computing system that includes one or more general purpose computers or processors. The code modules may be stored in any type of non-transitory computer-readable medium or other computer storage device. Some or all the methods may alternatively be embodied in specialized computer hardware. In addition, the components referred to herein may be implemented in hardware, software, firmware, or a combination thereof.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi, threaded processing, interrupt processing, or multiple processors or processor cores or on other parallel architectures, rather than sequentially. In addition, different tasks or processes can be performed by different machines and/or computing systems that can function together.

Any logical blocks, modules, and algorithm elements described or used in connection with the embodiments disclosed herein can be implemented as electronic hardware, computer software, or combinations of both. To clearly illustrate this interchangeability of hardware and software, various illustrative components, blocks, modules, and elements have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described or used in connection with the embodiments disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer, executable instructions. In another embodiment, a processor includes an FPGA or other programmable device that performs logic operations without processing computer, executable instructions. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, or algorithm described in connection with the embodiments disclosed herein can be embodied directly in hardware, in a software module stored in one or more memory devices and executed by one or more processors, or in a combination of the two. A software module can reside in RAM memory, flash memory, ROM memory, EPROM memory, EEPROM memory, registers, hard disk, a removable disk, a CD, ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix (s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive, rather the elements can be used separately or can be combined together under appropriate circumstances.

### PARTS LIST

quantum dot auto-annotator system 200
processor 202
non-transitory computer-readable medium 204
binarized threshold map 206
model-building module 208
statistical inferencing module 210
global state determination module 212
plurality of polygonal models 214
one or more orientation-based domains 216
probabilistic state vector 218
annotated charge stability diagram 220
extended point fingerprint 222
observation point 224
heat-flow clustering algorithm 226
ensemble of time-dependent kernels 228
central orientation-based domain 230
double-dot (DD) domain 232
central single-dot (SDC) domain 234
quantitative hexagon-ness score 236
model error score 238
plurality of intersection points 240
point fingerprint 242
gaps 244
overlaps 246

What is claimed is:

1. A method for automatically annotating empirical data from a quantum dot device, the method comprising:
receiving, by a processor (202), a binarized threshold map (206) derived from experimental measurements of charge stability in the quantum dot device, the binarized threshold map (206) representing charge transitions within a multi-dimensional parameter space;
generating, by the processor (202), a plurality of polygonal models (214) corresponding to a plurality of polytopal domains within the parameter space by performing a geometric analysis of the binarized threshold map (206);
clustering, by the processor (202), the plurality of polygonal models (214) into one or more orientation-based domains (216) based on a statistical analysis of geometric orientations of the plurality of polygonal models (214); and
generating, by the processor (202), an annotated charge stability diagram (220) by assigning a probabilistic state vector (218) to a plurality of pixel locations within the one or more orientation-based domains (216), the annotated charge stability diagram (220) providing a physically-principled classification of operational regimes of the quantum dot device.

2. The method of claim 1, wherein generating the plurality of polygonal models (214) further comprises:
emitting a dense set of rays from an observation point (224) to generate a point fingerprint (242) comprising a plurality of intersection points (240); and
fitting one of the plurality of polygonal models (214) to the point fingerprint (242) by performing a minimization of a normalized I² Hausdorff distance between the plurality of intersection points (240) and points defining the one of the plurality of polygonal models (214).

3. The method of claim 1, further comprising, prior to generating the plurality of polygonal models (214), identifying a plurality of candidate polygon centers by:
defining an initial grid of observation points (224) within the binarized threshold map (206); and
iteratively adjusting locations of the initial grid of observation points (224) toward centers of mass of their respective intersection points (240) until the locations of the observation points (224) stabilize.

4. The method of claim 1, wherein clustering the plurality of polygonal models (214) comprises applying a heat-flow clustering algorithm (226) to the geometric orientations to identify a plurality of dominant directions corresponding to the one or more orientation-based domains (216).

5. The method of claim 4, wherein applying the heat-flow clustering algorithm (226) comprises convolving point locations corresponding to the geometric orientations with an ensemble of time-dependent kernels (228) having parabolic scaling to identify persistent cluster centers.

6. The method of claim 1, wherein generating the annotated charge stability diagram (220) further comprises subdividing a central orientation-based domain (230) into a double-dot (DD) domain (232) and a central single-dot (SD_{C}) domain (234) based on a quantitative hexagon-ness score (236) calculated for each of the plurality of polygonal models (214) located within the central orientation-based domain (230).

7. The method of claim 6, wherein calculating the quantitative hexagon-ness score (236) is based on a first geometric ratio of a cell roof area to an upper cell area and a second geometric ratio of a cell floor area to a lower cell area of a respective polygonal model, the first and second geometric ratios being interpreted through a constant interaction model for coupled quantum dots.

8. The method of claim 2, further comprising, prior to clustering the plurality of polygonal models (214), filtering the plurality of polygonal models (214) by:
calculating a model error score (238) for each of the plurality of polygonal models (214) based on the minimized normalized I² Hausdorff distance; and
removing any of the plurality of polygonal models (214) whose model error score (238) is a statistical outlier relative to a distribution of all model error scores.

9. The method of claim 1, further comprising, after clustering and before generating the annotated charge stability diagram (220), a remodeling step comprising resolving overlaps (246) between adjacent polygonal models and filling in gaps (244) between the adjacent polygonal models to assign each pixel location in the binarized threshold map (206) to a unique polygonal model.

10. The method of claim 1, wherein the probabilistic state vector (218) comprises a plurality of components, each component quantifying a probability that a pixel location corresponds to a device state selected from the group consisting of a no-dot (ND) state, a left single-dot (SDL) state, a central single-dot (SD_{C}) state, a right single-dot (SDR) state, and a double-dot (DD) state.

11. A quantum dot auto-annotator system (200), comprising:
a processor (202); and
a non-transitory computer-readable medium (204) in communication with the processor (202), the non-transitory computer-readable medium (204) containing:
a data structure for a binarized threshold map (206) representing charge transitions in a multi-dimensional parameter space of a quantum dot device;
a model-building module (208) having logic for generating a plurality of polygonal models (214) from the binarized threshold map (206), wherein each of the plurality of polygonal models (214) corresponds to a polytopal domain within the parameter space;
a statistical inferencing module (210) having logic for clustering the plurality of polygonal models (214) into one or more orientation-based domains (216) based on geometric orientations of the plurality of polygonal models (214); and
a global state determination module (212) having logic for assigning a probabilistic state vector (218) to pixel locations within the one or more orientation-based domains (216) to generate an annotated charge stability diagram (220).

12. The quantum dot auto-annotator system (200) of claim 11, wherein the model-building module (208) further includes logic for generating an extended point fingerprint (222) for an observation point (224) within the binarized threshold map (206) and logic for fitting one of the plurality of polygonal models (214) to the extended point fingerprint (222) by minimizing a Hausdorff distance between a set of terminal points of the extended point fingerprint (222) and a set of points on the one of the plurality of polygonal models (214).

13. The quantum dot auto-annotator system (200) of claim 12, wherein the Hausdorff distance is a normalized I² Hausdorff distance.

14. The quantum dot auto-annotator system (200) of claim 11, wherein the statistical inferencing module (210) includes logic for a heat-flow clustering algorithm (226) for determining a plurality of dominant directions from the geometric orientations of the plurality of polygonal models (214).

15. The quantum dot auto-annotator system (200) of claim 14, wherein the heat-flow clustering algorithm (226) uses an ensemble of time-dependent kernels (228) with parabolic scaling to identify persistent cluster centers corresponding to the plurality of dominant directions.

16. The quantum dot auto-annotator system (200) of claim 11, wherein the global state determination module (212) further includes logic for subdividing a central orientation-based domain (230) of the one or more orientation-based domains (216) into a double-dot (DD) domain (232) and a central single-dot (SD_{C}) domain (234).

17. The quantum dot auto-annotator system (200) of claim 16, wherein the logic for subdividing the central orientation-based domain (230) uses a quantitative hexagon-ness score (236) calculated for each of the plurality of polygonal models (214) located within the central orientation-based domain (230).

18. The quantum dot auto-annotator system (200) of claim 17, wherein the quantitative hexagon-ness score (236) for one of the plurality of polygonal models (214) is a function of a first geometric ratio of a cell roof area to an upper cell area and a second geometric ratio of a cell floor area to a lower cell area of the one of the plurality of polygonal models (214).

19. The quantum dot auto-annotator system (200) of claim 12, wherein the statistical inferencing module (210) further includes logic for calculating a model error score (238) for each of the plurality of polygonal models (214) based on the minimized Hausdorff distance and logic for discarding any of the plurality of polygonal models (214) having the model error score (238) exceeding a statistical threshold relative to a distribution of all model error scores.

20. The quantum dot auto-annotator system (200) of claim 11, wherein each component of the probabilistic state vector (218) represents a probability for a device state selected from the group consisting of a no-dot (ND) state, a left single-dot (SDL) state, a central single-dot (SDC) state, a right single-dot (SDR) state, and a double-dot (DD) state.
